(19) United States
(12) Patent Application Publication
(10) Pub. No.: US 2026/0231547 A1
(43) Pub. Date: Aug. 6, 2026

(54) IMAGE PICKUP DEVICE AND ELECTRONIC DEVICE

(71) Applicant: SONY SEMICONDUCTOR SOLUTIONS CORPORATION, KANAGAWA (JP)

(72) Inventors: Chihiro ARAI, KANAGAWA (JP); Yoshiaki MASUDA, KANAGAWA (JP); Hiroki NAGATOME, KANAGAWA (JP); Atsuhiro ANDO, KANAGAWA (JP); Tetsuya MIZUGUCHI, KANAGAWA (JP); Daisuke ITO, KANAGAWA (JP); Hideki KOBAYASHI, KANAGAWA (JP); Yosuke NITTA, KANAGAWA (JP); Shunsuke FURUSE, KANAGAWA (JP)

(21) Appl. No.: 19/146,187

(22) PCT Filed: Jan. 15, 2024
(86) PCT No.: PCT/JP2024/000783

§ 371 Date: Jul. 7, 2025

(30) Foreign Application Priority Data
Jan. 13, 2023 (JP) 2023-003890

(51) Int. Cl. H10F 39/00

(52) U.S. Cl. CPC H10F 39/8067; H10F 39/011; H10F 39/804; H10F 39/8053; H10F 39/8057; H10F 39/8063

(57) ABSTRACT

Provided is an image pickup device including: a semiconductor substrate including a pixel region including a plurality of image pickup elements arranged in an array and an outer peripheral portion surrounding the pixel region; a glass substrate provided above the semiconductor substrate; a first sealing material that covers the outer peripheral portion of the semiconductor substrate and seals a gap between the semiconductor substrate and the glass substrate; and a plurality of columnar bodies provided at an inner side from the first sealing material on the semiconductor substrate.

### FIELD

The present disclosure relates to an image pickup device and an electronic device.

### BACKGROUND

In recent years, in electronic devices such as a mobile terminal device with a camera and a digital still camera, downsizing and thinning of an image pickup device incorporated therein have been advanced. As a method for downsizing and thinning of the image pickup device, a chip size package (CSP) structure has been used in recent years. For example, as a configuration example of the image pickup device, an image pickup device disclosed in Patent Literature 1 below can be exemplified.

### CITATION LIST

### Patent Literature

Patent Literature 1: JP 2007-184680 A

### SUMMARY

### Technical Problem

However, there is a case where a flare phenomenon occurs due to reflection of light in an image pickup device having a CSP structure, whereby image quality is degraded. In addition, in a case where it is attempted to suppress the occurrence of such a flare, there has been a limit to downsizing the image pickup device to a chip size level.

Thus, the present disclosure proposes an image pickup device that can easily perform downsizing to the chip size level while suppressing the occurrence of the flare and an electronic device.

### Solution to Problem

According to the present disclosure, there is provided an image pickup device. The image pickup device includes: a semiconductor substrate including a pixel region including a plurality of image pickup elements arranged in an array and an outer peripheral portion surrounding the pixel region; a glass substrate provided above the semiconductor substrate; a first sealing material that covers the outer peripheral portion of the semiconductor substrate and seals a gap between the semiconductor substrate and the glass substrate; and a plurality of columnar bodies provided at an inner side from the first sealing material on the semiconductor substrate.

Furthermore, according to the present disclosure, there is provided an electronic device equipped with an image pickup device. The image pickup device includes: a semiconductor substrate including a pixel region including a plurality of image pickup elements arranged in an array and an outer peripheral portion surrounding the pixel region; a glass substrate provided above the semiconductor substrate; a first sealing material that covers the outer peripheral portion of the semiconductor substrate and seals a gap between the semiconductor substrate and the glass substrate; and a plurality of columnar bodies provided at an inner side from the first sealing material on the semiconductor substrate.

### BRIEF DESCRIPTION OF DRAWINGS

FIG. 1 is a block diagram illustrating a schematic configuration example of an electronic device equipped with an image pickup device according to embodiments of the present disclosure.

FIG. 2 is a block diagram illustrating a schematic configuration example of the image pickup device of a CMOS image sensor type according to the embodiments of the present disclosure.

FIG. 3 is a circuit diagram illustrating a configuration example of a pixel according to the embodiments of the present disclosure.

FIG. 4 is a diagram illustrating a stacked structure example of a chip of the image pickup device according to the embodiments of the present disclosure.

FIG. 5 is a cross-sectional view illustrating a basic cross-sectional structure example of the image pickup device according to the embodiments of the present disclosure.

FIG. 6A is a cross-sectional view illustrating a cross-sectional structure example of the image pickup device having a cavity-less structure.

FIG. 6B is an explanatory diagram for explaining a flare phenomenon occurring in the image pickup device having the cavity-less structure.

FIG. 7A is a cross-sectional view illustrating a cross-sectional structure example of the image pickup device having a cavity structure.

FIG. 7B is an explanatory diagram for explaining a flare phenomenon occurring in the image pickup device having the cavity structure.

FIG. 8A is a plan view illustrating a structure example of the image pickup device according to a first embodiment of the present disclosure.

FIG. 8B is a cross-sectional view illustrating the structure example of the image pickup device according to the first embodiment of the present disclosure.

FIG. 9 is a cross-sectional view illustrating a structure example of the image pickup device according to a first modification of the first embodiment of the present disclosure.

FIG. 10 is a plan view (part 1) illustrating a structure example of the image pickup device according to a second modification of the first embodiment of the present disclosure.

FIG. 11 is a plan view (part 2) illustrating a structure example of the image pickup device according to the second modification of the first embodiment of the present disclosure.

FIG. 12 is a plan view (part 3) illustrating a structure example of the image pickup device according to the second modification of the first embodiment of the present disclosure.

FIG. 13 is a cross-sectional view illustrating a Structure example of a pillar according to a third modification of the first embodiment of the present disclosure.

FIG. 14A is a plan view illustrating a structure example of the image pickup device according to a second embodiment of the present disclosure.

FIG. 14B is an enlarged view illustrating a structure example of the image pickup device according to the second embodiment of the present disclosure.

FIG. 15A is a process cross-sectional view (part 1) illustrating a first example of a manufacturing method for the image pickup device according to a third embodiment of the present disclosure.

FIG. 15B is a process cross-sectional view (part 2) illustrating the first example of the manufacturing method for the image pickup device according to the third embodiment of the present disclosure.

FIG. 16A is a process cross-sectional view (part 1) illustrating a second example of the manufacturing method for the image pickup device according to the third embodiment of the present disclosure.

FIG. 16B is a process cross-sectional view (part 2) illustrating the second example of the manufacturing method for the image pickup device according to the third embodiment of the present disclosure.

FIG. 17 is a cross-sectional view illustrating a structure example of the image pickup device according to a fourth embodiment of the present disclosure.

FIG. 18A is a cross-sectional view illustrating a structure example of the image pickup device according to a first modification of the fourth embodiment of the present disclosure.

FIG. 18B is a plan view illustrating the structure example of the image pickup device according to the first modification of the fourth embodiment of the present disclosure.

FIG. 19A is a cross-sectional view illustrating a Structure example of the image pickup device according to a second modification of the fourth embodiment of the present disclosure.

FIG. 19B is a plan view illustrating the structure example of the image pickup device according to the second modification of the fourth embodiment of the present disclosure.

FIG. 20 is an explanatory diagram for explaining the first and second modifications of the fourth embodiment of the present disclosure.

FIG. 21 is a cross-sectional view illustrating a structure example of the image pickup device according to a third modification of the fourth embodiment of the present disclosure.

FIG. 22 is a cross-sectional view illustrating a Structure example of the image pickup device according to a fourth modification of the fourth embodiment of the present disclosure.

FIG. 23 is a process cross-sectional view illustrating a first example of the manufacturing method for the image pickup device according to a fifth embodiment of the present disclosure.

FIG. 24 is a process cross-sectional view illustrating a second example of the manufacturing method for the image pickup device according to the fifth embodiment of the present disclosure.

FIG. 25 is a cross-sectional view illustrating a structure example of the image pickup device according to a sixth embodiment of the present disclosure.

FIG. 26 is a plan view illustrating the structure example of the image pickup device according to the sixth embodiment of the present disclosure.

FIG. 27A is a plan view illustrating a structure example of the image pickup device according to a modification of the sixth embodiment of the present disclosure.

FIG. 27B is an enlarged view illustrating the structure example of the image pickup device according to the modification of the sixth embodiment of the present disclosure.

FIG. 28 is a process cross-sectional view illustrating a first example of the manufacturing method for the image pickup device according to the sixth embodiment of the present disclosure.

FIG. 29 is a process cross-sectional view illustrating a second example of the manufacturing method for the image pickup device according to the sixth embodiment of the present disclosure.

FIG. 30 is a cross-sectional view (part 1) illustrating a structure example of the image pickup device according to a seventh embodiment of the present disclosure.

FIG. 31 is a cross-sectional view (part 2) illustrating a structure example of the image pickup device according to the seventh embodiment of the present disclosure.

FIG. 32 is a cross-sectional view (part 3) illustrating a structure example of the image pickup device according to the seventh embodiment of the present disclosure.

FIG. 33 is a cross-sectional view illustrating a structure example of the image pickup device according to a first modification of the seventh embodiment of the present disclosure.

FIG. 34 is a cross-sectional view (part 1) illustrating a structure example of the image pickup device according to a second modification of the seventh embodiment of the present disclosure.

FIG. 35 is a cross-sectional view (part 2) illustrating a structure example of the image pickup device according to the second modification of the seventh embodiment of the present disclosure.

FIG. 36 is a cross-sectional view (part 3) illustrating a structure example of the image pickup device according to the second modification of the seventh embodiment of the present disclosure.

FIG. 37 is an explanatory diagram for explaining the first and second modifications of the seventh embodiment of the present disclosure.

FIG. 38 is a plan view illustrating a structure example of the image pickup device according to the first and second modifications of the seventh embodiment of the present disclosure.

FIG. 39 is a cross-sectional view (part 1) illustrating a structure example of the image pickup device according to a third modification of the seventh embodiment of the present disclosure.

FIG. 40 is a cross-sectional view (part 2) illustrating a structure example of the image pickup device according to the third modification of the seventh embodiment of the present disclosure.

FIG. 41 is a cross-sectional view (part 3) illustrating a structure example of the image pickup device according to the third modification of the seventh embodiment of the present disclosure.

FIG. 42 is a plan view illustrating a structure example of the image pickup device according to a fourth modification of the seventh embodiment of the present disclosure.

FIG. 43A is a process cross-sectional view (part 1) illustrating a first example of the manufacturing method for the image pickup device according to the seventh embodiment of the present disclosure.

FIG. 43B is a process cross-sectional view (part 2) illustrating the first example of the manufacturing method for the image pickup device according to the seventh embodiment of the present disclosure.

FIG. 44A is a process cross-sectional view (part 1) illustrating a second example of the manufacturing method for the image pickup device according to the seventh embodiment of the present disclosure.

FIG. 44B is a process cross-sectional view (part 2) illustrating the second example of the manufacturing method for the image pickup device according to the seventh embodiment of the present disclosure.

FIG. 45 is a process cross-sectional view illustrating a third example of the manufacturing method for the image pickup device according to the seventh embodiment of the present disclosure.

FIG. 46 is a process cross-sectional view illustrating a fourth example of the manufacturing method for the image pickup device according to the seventh embodiment of the present disclosure.

FIG. 47 is a process cross-sectional view illustrating a fifth example of the manufacturing method for the image pickup device according to the seventh embodiment of the present disclosure.

FIG. 48 is a block diagram illustrating an example of a schematic functional configuration of a smartphone.

FIG. 49 is a view depicting an example of a schematic configuration of an endoscopic surgery system.

FIG. 50 is a block diagram depicting an example of a functional configuration of a camera head and a camera control unit (CCU).

### DESCRIPTION OF EMBODIMENTS

Hereinafter, a description will be given in detail of preferred embodiments of the present disclosure with reference to the accompanying drawings. Note that, in the present specification and the drawings, components having substantially the same functional configuration are denoted by the same reference numerals to omit duplicate description. In addition, in the present specification and the drawings, a plurality of components having substantially the same or similar functional configuration may be distinguished from each other by attaching different alphabets after the same reference numeral. However, in a case where it is not particularly necessary to distinguish the plurality of components having substantially the same or similar functional configuration from each other, only the same reference numeral is attached.

In addition, the drawings referred to in the following description are drawings for promoting the description and understanding of an embodiment of the present disclosure, and shapes, dimensions, ratios, and the like illustrated in the drawings may be different from actual ones for the sake of clarity. Further, an image pickup device illustrated in the drawings can be appropriately modified in design in consideration of the following description and known techniques.

Description of specific shapes in the following description does not mean only geometrically defined shapes. Specifically, the description of specific shapes in the following description includes a case where there is an allowable difference (error/distortion) in an image pickup device (semiconductor device), a manufacturing process thereof, and use/operation thereof, and a shape similar to the shapes. For example, in the following description, the expression “circular shape” or “substantially circular shape” means that the shape is not limited to a perfect circle but includes a shape similar to a perfect circle such as an elliptical shape.

Further, in the following description, “electrically connecting” means connecting a plurality of elements to each other directly or indirectly via other elements.

Note that, the description will be given in the following order.
1. Background to creation of embodiments of present disclosure
1.1 Configuration example of electronic device
1.2 Configuration example of image pickup device
1.3 Configuration example of pixel
1.4 Basic operation example of pixel
1.5 Stacked structure example of image pickup device
1.6 Cross-sectional structure example of image pickup device
1.7 Background
2. First embodiment
2.1 Detailed configuration
2.2 First modification
2.3 Second modification
2.4 Third modification
3. Second embodiment
4. Third embodiment
4.1 First example of manufacturing method
4.2 Second example of manufacturing method
5. Fourth embodiment
5.1 Detailed configuration
5.2 First modification
5.3 Second modification
5.4 Third modification
5.5 Fourth modification
6. Fifth embodiment
6.1 First example of manufacturing method
6.2 Second example of manufacturing method
6.3 Third example of manufacturing method
7. Sixth embodiment
7.1 Detailed configuration
7.2 Modification
7.3 Manufacturing method
8. Seventh embodiment
8.1 Detailed configuration
8.2 First modification
8.3 Second modification
8.4 Third modification
8.5 Fourth modification
8.6 First example of manufacturing method
8.7 Second example of manufacturing method
8.8 Third example of manufacturing method
8.9 Fourth example of manufacturing method
8.10 Fifth example of manufacturing method
9. Conclusion
10. Application example
10.1 Application example to smartphone
10.2 Application example to endoscopic surgery system
11. Supplement

### 1. Background to Creation of Embodiments of Present Disclosure

### 1.1 Configuration Example of Electronic Device

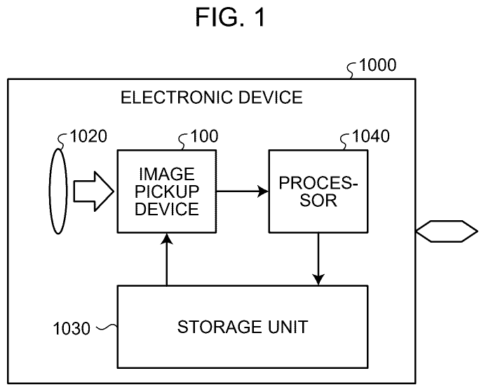

First, before describing embodiments of the present disclosure, a description will be given of a background to creation of the embodiments of the present disclosure by the present inventors. First, with reference to FIG. 1, a description will be given of an electronic device that can be equipped with an image pickup device according to the embodiments of the present disclosure. FIG. 1 is a block diagram illustrating a schematic configuration example of an electronic device 1000 equipped with an image pickup device 100 according to the embodiments of the present disclosure.

Specifically, as illustrated in FIG. 1, the electronic device 1000 mainly includes, for example, an image pickup lens 1020, the image pickup device 100, a storage unit 1030, and a processor 1040. Hereinafter, each functional unit of the electronic device 1000 will be sequentially described.

The image pickup lens 1020 is an example of an optical system that condenses incident light and forms an image thereof on a light receiving surface of the image pickup device 100. The light receiving surface refers to a surface on which a plurality of image pickup elements included in the image pickup device 100 is arranged. The image pickup device 100 photo-electrically converts the incident light to generate image data. In addition, the image pickup device 100 executes predetermined signal processing such as noise removal and white balance adjustment on the generated image data. Note that a configuration example of the image pickup device 100 will be described later.

The storage unit 1030 includes, for example, a flash memory, a dynamic random access memory (DRAM), a static random access memory (SRAM), or the like, and records image data or the like input from the image pickup device 100.

The processor 1040 includes, for example, a central processing unit (CPU) or the like, and may include an application processor that executes an operating system, various types of application software, or the like, a graphics processing unit (GPU), a baseband processor, or the like. The processor 1040 executes various types of processing as necessary on the image data input from the image pickup device 100, the image data read from the storage unit 1030, and the like, executes display to a user, and transmits the image data to the outside via a predetermined network.

### 1.2 Configuration Example of Image Pickup Device

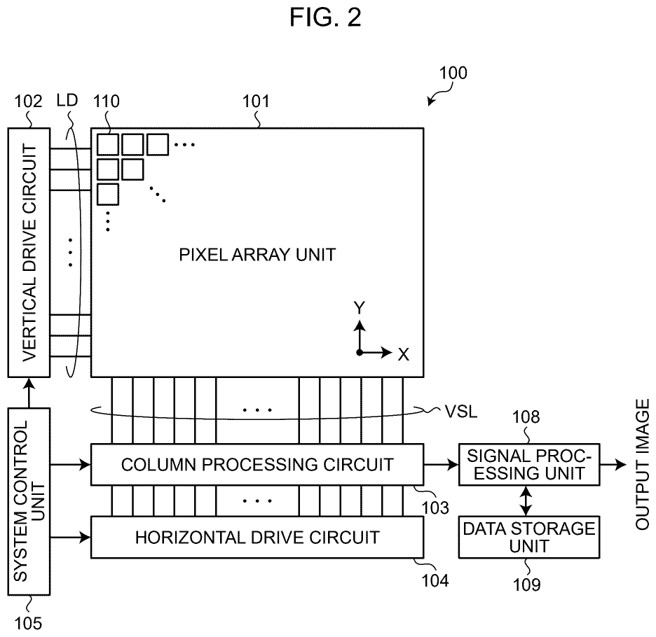

Next, a configuration example of the image pickup device 100 will be described with reference to FIG. 2.

FIG. 2 is a block diagram illustrating a schematic configuration example of the image pickup device 100 of a complementary metal-oxide-semiconductor (CMOS) image sensor type according to the embodiments of the present disclosure. Here, the CMOS image sensor is an image sensor created by application or partial use of a CMOS process.

The image pickup device 100 according to the embodiments of the present disclosure may be of a so-called back-illuminated type in which the incident surface is on a surface (hereinafter, referred to as a back surface) side opposite to the element formation surface in the semiconductor substrate, or may be of a so-called front illuminated type in which the incident surface is on a front surface side.

As illustrated in FIG. 2, the image pickup device 100 mainly includes, for example, a pixel array unit 101, a vertical drive circuit 102, a column processing circuit 103, a horizontal drive circuit 104, a system control unit 105, a signal processing unit 108, and a data storage unit 109. In the following description, the vertical drive circuit 102, the column processing circuit 103, the horizontal drive circuit 104, the system control unit 105, the signal processing unit 108, and the data storage unit 109 are also referred to as peripheral circuits.

The pixel array unit 101 has a configuration in which pixels 110 each having an image pickup element that generates and accumulates charges according to an amount of received light are arranged in a row direction and a column direction, that is, in a two-dimensional lattice (hereinafter, referred to as in an array) in a matrix.

Here, the row direction refers to an arrangement direction (lateral direction in the drawing) of the pixels 110 in a pixel row, and the column direction refers to an arrangement direction (longitudinal direction in the drawing) of the pixels 110 in a pixel column. Details of a specific circuit configuration example of the pixels 110 will be described later.

In the pixel array unit 101, a pixel drive line LD is wired along the row direction for each pixel row, and a vertical signal line VSL is wired along the column direction for each pixel column with respect to a pixel arrangement in an array. The pixel drive line LD transmits a drive signal for driving when a signal is read from a pixel. In FIG. 2, the pixel drive lines LD each are illustrated as one wiring line, but are not limited to one wiring line. One end of the pixel drive line LD is connected to an output end corresponding to each row of the vertical drive circuit 102.

The vertical drive circuit 102 includes a shift register, an address decoder, and the like, and drives each pixel 110 of the pixel array unit 101 at the same time for all pixels or in units of rows. That is, the vertical drive circuit 102 constitutes a driving unit that controls operation of each pixel 110 of the pixel array unit 101 together with the system control unit 105 that controls the vertical drive circuit 102. Although a specific configuration of the vertical drive circuit 102 is not illustrated, the vertical drive circuit generally includes two scanning systems of a read scanning system and a sweep scanning system.

In order to read a signal from the pixel 110, the read scanning system sequentially selects and scans the pixel 110 of the pixel array unit 101 in units of rows. The signal read from the pixel 110 is an analog signal. The sweep scanning system performs sweep scanning on a read row on which read scanning is performed by the read scanning system prior to the read scanning by an exposure time.

By the sweep scanning by the sweep scanning system, unnecessary charges are swept out from the image pickup element of the pixel 110 in the read row, whereby the image pickup element is reset. Then, by sweeping out (resetting) unnecessary charges by the sweep scanning system, a so-called electronic shutter operation is performed. Here, the electronic shutter operation refers to an operation of discarding charges of the image pickup element and newly starting exposure (starting accumulation of charges).

The signal read by a read operation by the read scanning system corresponds to an amount of light received after an immediately preceding read operation or electronic shutter operation. A period from a read timing by the immediately preceding read operation or a sweep timing by the electronic shutter operation to a read timing by a current read operation is a charge accumulation period (also referred to as an exposure period) in the pixel 110.

The signal output from each pixel 110 of the pixel row selectively scanned by the vertical drive circuit 102 is input to the column processing circuit 103 through each of the vertical signal lines VSL for each pixel column. The column processing circuit 103 performs predetermined signal processing on the signal output from each pixel 110 of the selected row through the vertical signal line VSL for each pixel column of the pixel array unit 101, and temporarily holds the pixel signal after the signal processing.

Specifically, the column processing circuit 103 performs at least noise removal processing, for example, correlated double sampling (CDS) processing or double data sampling (DDS) processing, as the signal processing. For example, the CDS processing removes fixed pattern noise unique to the pixel 110, such as reset noise, threshold variation of an amplification transistor in the pixel, or the like. In addition, the column processing circuit 103 also has, for example, an analog-digital (AD) conversion function, converts an analog pixel signal read from the image pickup element into a digital signal, and outputs the digital signal.

The horizontal drive circuit 104 includes a shift register, an address decoder, and the like, and sequentially selects a readout circuit (hereinafter, referred to as a pixel circuit) corresponding to a pixel column of the column processing circuit 103. By the selective scanning by the horizontal drive circuit 104, pixel signals subjected to signal processing for each pixel circuit in the column processing circuit 103 are sequentially output.

The system control unit 105 includes a timing generator or the like that generates various timing signals, and performs drive control of the vertical drive circuit 102, the column processing circuit 103, the horizontal drive circuit 104, and the like on the basis of various timings generated by the timing generator.

The signal processing unit 108 has at least an arithmetic processing function, and performs various types of signal processing such as arithmetic processing on the pixel signal output from the column processing circuit 103. The data storage unit 109 temporarily stores data necessary for signal processing in the signal processing unit 108.

Note that the image data output from the signal processing unit 108 may be, for example, subjected to predetermined processing in the processor 1040 or the like in the electronic device 1000 equipped with the image pickup device 100, or transmitted to the outside via a predetermined network.

Note that, in the embodiments of the present disclosure, the configuration of the image pickup device 100 is not limited to the example illustrated in FIG. 2.

### 1.3 Configuration Example of pixel

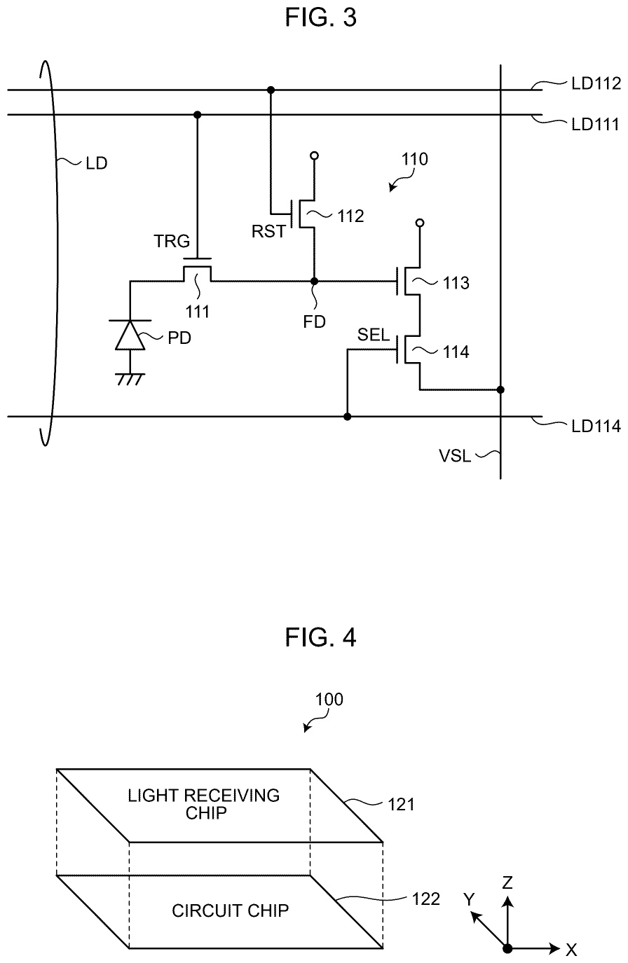

Next, details of a specific circuit configuration example of the pixel 110 will be described with reference to FIG. 3. FIG. 3 is a circuit diagram illustrating a configuration example of the pixel 110 according to the embodiments of the present disclosure. As illustrated in FIG. 3, the pixel 110 mainly includes a photodiode (image pickup element) PD, a transfer transistor 111, a reset transistor 112, an amplification transistor 113, a selection transistor 114, and a floating diffusion layer FD.

The gate of the selection transistor 114 is electrically connected to a selection transistor drive line LD114 included in the pixel drive line LD, and the gate of the reset transistor 112 is electrically connected to a reset transistor drive line LD112 included in the pixel drive line LD. In addition, the gate of the transfer transistor 111 is electrically connected to a transfer transistor drive line LD111 included in the pixel drive line LD. Further, the drain of the amplification transistor 113 is connected via the selection transistor 114 to the vertical signal line VSL having one end connected to the column processing circuit 103.

In the following description, the reset transistor 112, the amplification transistor 113, and the selection transistor 114 are also collectively referred to as a pixel circuit. The pixel circuit may include the floating diffusion layer FD and/or the transfer transistor 111.

The photodiode PD is an element that photo-electrically converts incident light. The transfer transistor 111 transfers charges generated in the photodiode PD. The floating diffusion layer FD accumulates the charges transferred by the transfer transistor 111.

The amplification transistor 113 causes a pixel signal having a voltage value corresponding to the charges accumulated in the floating diffusion layer FD to appear in the vertical signal line VSL. The reset transistor 112 releases the charges accumulated in the floating diffusion layer FD. The selection transistor 114 selects the pixel 110 to be read.

The anode of the photodiode PD is grounded, and the cathode is electrically connected to the source of the transfer transistor 111. The drain of the transfer transistor 111 is electrically connected to the source of the reset transistor 112 and the gate of the amplification transistor 113, and a node that is a connection point of these transistors forms the floating diffusion layer FD. Note that the drain of the reset transistor 112 is connected to a vertical reset input line (not illustrated).

The source of the amplification transistor 113 is connected to a vertical current supply line (not illustrated). The drain of the amplification transistor 113 is electrically connected to the source of the selection transistor 114, and the drain of the selection transistor 114 is electrically connected to the vertical signal line VSL.

The floating diffusion layer FD converts the accumulated charges into a voltage of a voltage value corresponding to an amount of the charges. Note that the floating diffusion layer FD may be, for example, a capacitance to ground. Note that, in the embodiments of the present disclosure, the floating diffusion layer FD is not limited to the capacitance to ground. For example, the floating diffusion layer FD may be a capacitance added by intentional connection of a capacitor or the like to a node to which the drain of the transfer transistor 111, the source of the reset transistor 112, and the gate of the amplification transistor 113 are connected.

Note that, in the embodiments of the present disclosure, the circuit configuration of the pixel 110 is not limited to the example illustrated in FIG. 3.

### 1.4 Basic Operation Example of Pixel

Next, a basic operation example of the pixel 110 will be described with reference to FIG. 3. First, the reset transistor 112 controls discharge (reset) of charges accumulated in the floating diffusion layer FD in accordance with a reset signal RST supplied from the vertical drive circuit 102 via the reset transistor drive line LD112. Note that, by turning on the transfer transistor 111 when the reset transistor 112 is turned on, it is also possible to discharge (reset) charges accumulated in the photodiode PD in addition to the charges accumulated in the floating diffusion layer FD.

When the reset signal RST at the High level is input to the gate of the reset transistor 112, the floating diffusion layer FD is clamped to a voltage applied through the vertical reset input line. As a result, the charges accumulated in the floating diffusion layer FD are discharged (reset).

In addition, when the reset signal RST at the Low level is input to the gate of the reset transistor 112, the floating diffusion layer FD is electrically disconnected from the vertical reset input line and enters a floating state.

The photodiode PD photo-electrically converts incident light and generates charges corresponding to an amount of the incident light. The generated charges are accumulated on the cathode side of the photodiode PD. The transfer transistor 111 controls transfer of the charges from the photodiode PD to the floating diffusion layer FD in accordance with a transfer control signal TRG supplied from the vertical drive circuit 102 via the transfer transistor drive line LD111.

For example, when the transfer control signal TRG at the High level is input to the gate of the transfer transistor 111, the charges accumulated in the photodiode PD are transferred to the floating diffusion layer FD. On the other hand, when the transfer control signal TRG at the Low level is supplied to the gate of the transfer transistor 111, the transfer of the charges from the photodiode PD is stopped.

As described above, the floating diffusion layer FD has a function of converting the charges transferred from the photodiode PD via the transfer transistor 111 into a voltage of a voltage value corresponding to the amount of the charges. Thus, in the floating state in which the reset transistor 112 is turned off, a potential of the floating diffusion layer FD is modulated according to the amount of the charges accumulated therein.

The amplification transistor 113 functions as an amplifier using a potential fluctuation of the floating diffusion layer FD connected to the gate thereof as an input signal, and an output voltage signal thereof appears as the pixel signal in the vertical signal line VSL via the selection transistor 114.

The selection transistor 114 controls the appearance of the pixel signal by the amplification transistor 113 in the vertical signal line VSL in accordance with a selection control signal SEL supplied from the vertical drive circuit 102 via the selection transistor drive line LD114. For example, when the selection control signal SEL at the High level is input to the gate of the selection transistor 114, the pixel signal by the amplification transistor 113 appears in the vertical signal line VSL. On the other hand, when the selection control signal SEL at the Low level is input to the gate of the selection transistor 114, the appearance of the pixel signal in the vertical signal line VSL is stopped. As a result, it is possible to extract only the output of the selected pixel 110 in the vertical signal line VSL to which the plurality of pixels 110 is connected.

### 1.5 Stacked Structure Example of Image Pickup Device

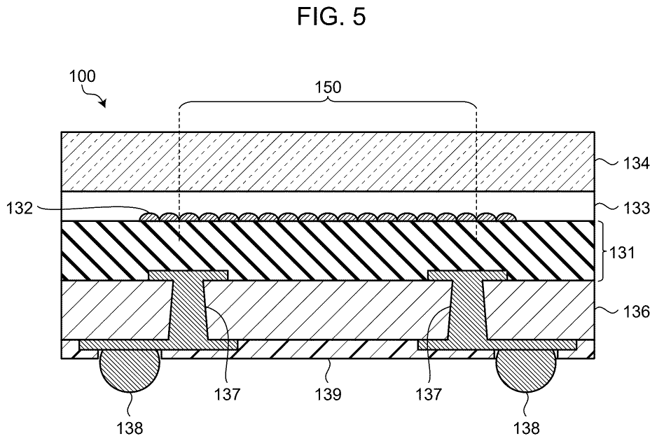

Next, a stacked structure example of the image pickup device 100 will be described with reference to FIG. 4.

FIG. 4 is a diagram illustrating a stacked structure example of a chip of the image pickup device 100 according to the embodiments of the present disclosure. As illustrated in FIG. 4, the image pickup device 100 has a stacked structure in which a light receiving chip 121 and a circuit chip 122 are vertically stacked. The light receiving chip 121 is, for example, a semiconductor chip including the pixel array unit 101 in which the photodiodes (image pickup elements) PD are arranged, and the circuit chip 122 is, for example, a semiconductor chip including the pixel circuit illustrated in FIG. 3, the peripheral circuits in FIG. 2, and the like.

For bonding the light receiving chip 121 and the circuit chip 122 together, for example, so-called direct bonding can be used in which the bonding surfaces are flattened and the bonding surfaces are bonded together by an inter electronic force. However, in the embodiments of the present disclosure, not limited thereto, it is also possible to use, for example, so-called Cu-Cu bonding in which copper (Cu) electrode pads formed on the bonding surfaces are bonded together, and in addition, bump bonding, or the like.

In addition, the light receiving chip 121 and the circuit chip 122 are electrically connected together via a connection portion such as a through-silicon via (TSV) penetrating the semiconductor substrate, for example. For the connection using the TSV, it is possible to adopt, for example, a so-called twin TSV method in which two TSVs, that is, a TSV provided in the light receiving chip 121 and a TSV provided from the light receiving chip 121 to the circuit chip 122 are connected together on an outer surface of the chip, a so-called shared TSV method in which the light receiving chip 121 and the circuit chip 122 are connected together by a TSV penetrating from the light receiving chip 121 to the circuit chip 122, or the like.

However, when Cu-Cu bonding or bump bonding is used for bonding the light receiving chip 121 and the circuit chip 122 together, both are electrically connected together via a Cu-Cu bonding portion or a bump bonding portion.

Note that, in the embodiments of the present disclosure, the stacked structure of the chip of the image pickup device 100 is not limited to the example illustrated in FIG. 4.

### 1.6 Cross-Sectional Structure Example of Image Pickup Device

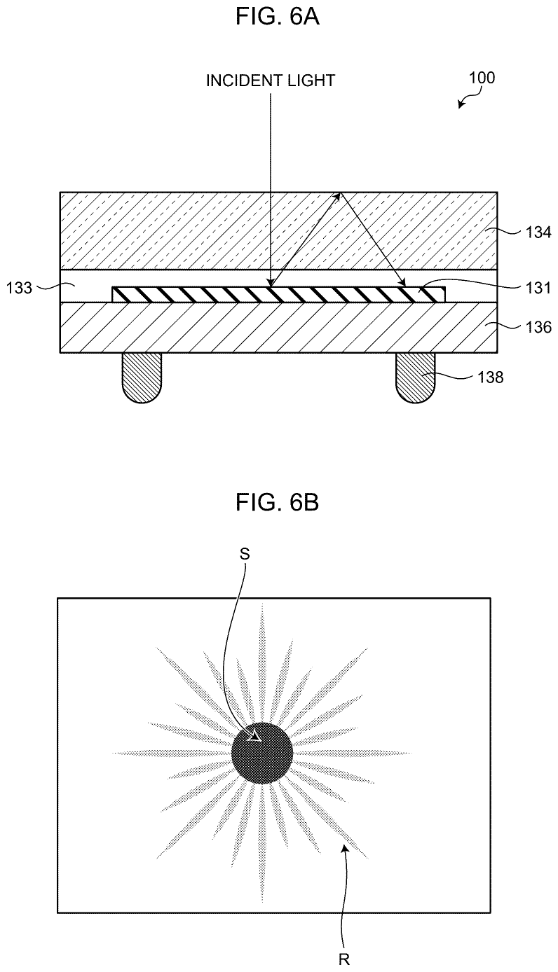

Next, with reference to FIG. 5, a description will be given of a cross-sectional structure example of the image pickup device 100 packaged as a so-called CSP structure.

FIG. 5 is a cross-sectional view illustrating a basic cross-sectional structure example of the image pickup device 100 according to the embodiments of the present disclosure. Note that, in the present description, as an example, a case will be described where the image pickup device 100 is a back-illuminated type, but the image pickup device may be a front-illuminated type as described above.

As illustrated in FIG. 5, the image pickup device 100 includes a semiconductor substrate 131 on which the photodiodes (image pickup elements) PD of the plurality of pixels 110 are arranged in a matrix, and a semiconductor substrate 136 on which the remaining circuit elements (see FIG. 3) and peripheral circuits (see FIG. 2) of the pixels 110 are provided. The photodiodes PD in the pixels 110 may be arranged in a matrix on the back surface side of the semiconductor substrate 131, for example. Note that the semiconductor substrate 131 may be, for example, a semiconductor substrate of the light receiving chip 121 in FIG. 4, and the semiconductor substrate 136 may be, for example, a semiconductor substrate of the circuit chip 122 in FIG. 4.

The back surface side (upper surface side in the drawing) of the semiconductor substrate 131 is provided with a plurality of on-chip lenses 132, a glass substrate 134, and a resin layer 133. On the other hand, the back surface side (lower surface side in the drawing) of the semiconductor substrate 131 bonded to the front surface side (lower surface side in the drawing) of the semiconductor substrate 136 is provided with a passivation 139, an extended electrode 137, and a ball bump 138.

The on-chip lenses 132 are provided for the respective photodiodes PD arranged on the back surface side of the semiconductor substrate 131, for example. Thus, the on-chip lenses 132 are arranged in a matrix on the back surface of the semiconductor substrate 131. Each on-chip lens 132 has a curvature for condensing incident light on a light receiving surface of the photodiode PD corresponding thereto.

The glass substrate 134 is, for example, a member for protecting the back surface (corresponding to the light receiving surface) of the semiconductor substrate 131 and maintaining the physical strength of the image pickup device 100.

The resin layer 133 is, for example, an optically transparent epoxy-based resin, low melting point glass, ultraviolet curable resin, or the like, and has a role of bringing a surface on which diffracted light of light reflected by the on-chip lens 132 or the like is totally reflected close to the light receiving surface of the semiconductor substrate 131 by covering at least an effective pixel region 150 on the back surface of the semiconductor substrate 131 in addition to a role of bonding the glass substrate 134 substrate to the semiconductor substrate 131. Note that the effective pixel region 150 refers to a rectangular region that can be used to generate image data and in which the photodiodes PD are arranged that are not covered with a light shielding film (not illustrated), for example.

Note that the resin layer 133 is not limited to being provided so as to cover the entire semiconductor substrate 131, and may be provided so as to cover only the outer peripheral portion of the semiconductor substrate 131. In such a case, there is a cavity (gap) filled with air between the effective pixel region 150 provided in the central portion of the semiconductor substrate 131 and the glass substrate 134. Note that the inside of the cavity may be filled with air, a gas such as nitrogen (N2) or argon (Ar), or may be a vacuum.

Note that, in the present specification, in a case where the resin layer 133 is provided so as to cover the entire semiconductor substrate 131, since there is no cavity on the effective pixel region 150, the structure is referred to as a cavity-less structure. On the other hand, in a case where the resin layer 133 is provided so as to cover only the outer peripheral portion of the semiconductor substrate 131, since there is a cavity on the effective pixel region 150, the structure is referred to as a cavity structure.

Note that, although not illustrated in FIG. 5, the surfaces where the semiconductor substrate 131 and the semiconductor substrate 136 are bonded may each be provided with a wiring layer including an insulating film including a wiring line that connects the pixel 110 and the peripheral circuits together inside. In this case, as the insulating film of the wiring layer, it is possible to use, for example, a silicon oxide film (SiO₂), a silicon nitride film (SiN), or the like.

The passivation 139 is, for example, a film formed by use of photosensitive polyimide, polybenzoxazole (PBO), a silicone-based resin material, or the like, and has a role of protecting the back surface (lower surface in the drawing) side of the semiconductor substrate 136 and the extended electrode 137.

The extended electrode 137 includes, for example, a conductive material such as metal, and extends electrical connection to the peripheral circuits or the like provided on the semiconductor substrate 136 to the back surface of the semiconductor substrate 136.

The ball bump 138 is, for example, a solder ball or the like provided at an exposed portion of the extended electrode 137, and is an external terminal for electrically connecting the image pickup device 100 to a circuit board or the like. However, the structure of the external terminal is not limited to a structure using the ball bump 138, and it is also possible to adopt a structure, for example, a flat pad or the like.

Note that the example illustrated in FIG. 5 is a basic cross-sectional structure example of the image pickup device 100 packaged as a so-called CSP structure, and the embodiments of the present disclosure are not limited to the example illustrated in FIG. 5.

### 1.7 Background

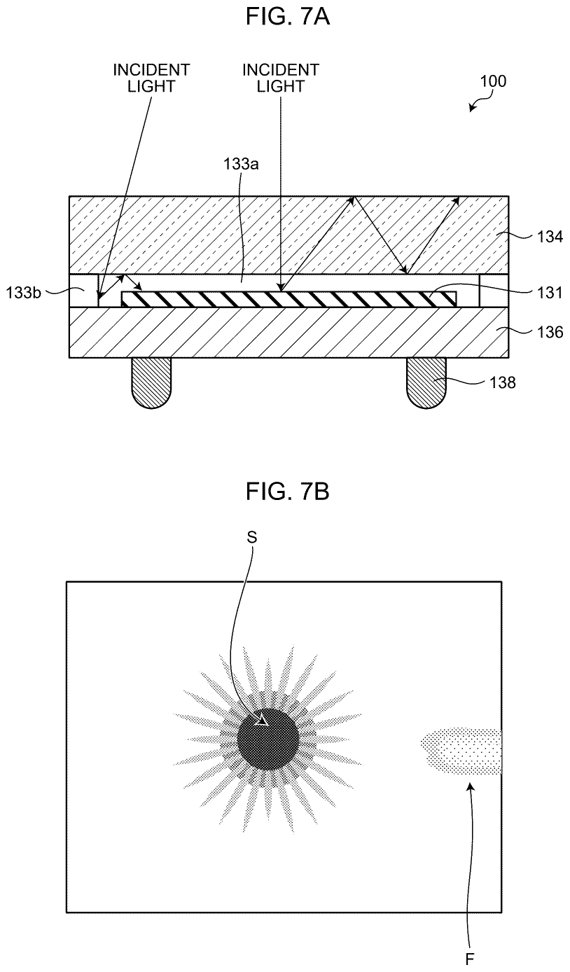

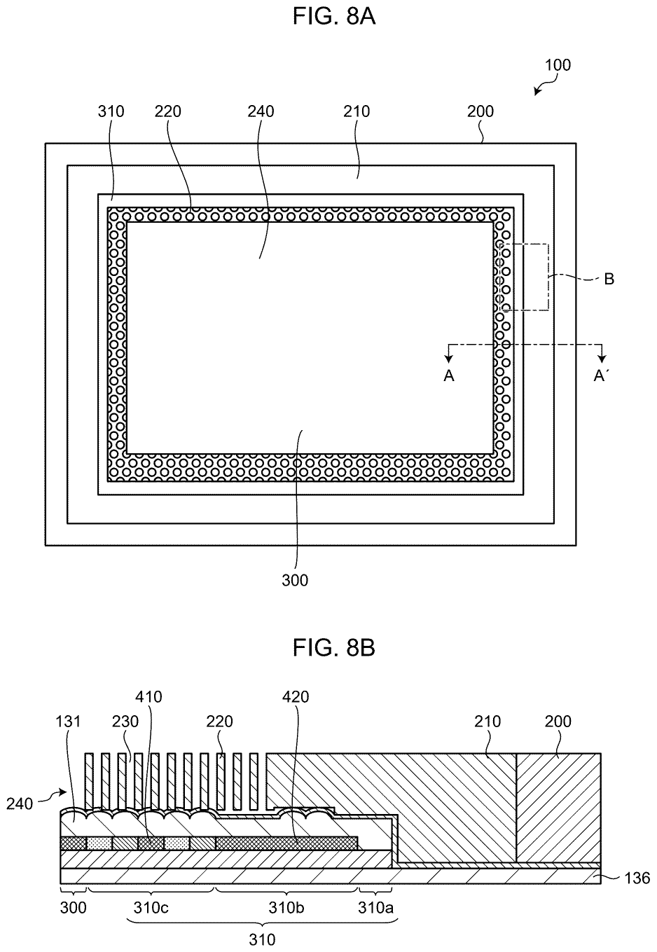

Next, with reference to FIGS. 6A to 7B, a description will be given of a flare phenomenon that occurs in the image pickup device 100, which is a background for the inventors to create the embodiments of the present disclosure. FIG. 6A is a cross-sectional view illustrating a cross-sectional structure example of the image pickup device 100 having the cavity-less structure, and FIG. 6B is an explanatory diagram for explaining a flare phenomenon occurring in the image pickup device 100 having the cavity-less structure. In addition, FIG. 7A is a cross-sectional view illustrating a cross-sectional structure example of the image pickup device 100 having the cavity structure, and FIG. 7B is an explanatory diagram for explaining a flare phenomenon occurring in the image pickup device 100 having the cavity structure. Note that FIGS. 6B and 7B are diagrams schematically illustrating an image obtained by the image pickup device 100, in which black and white on an actual image are reversed for easy understanding.

As illustrated in FIG. 6A, the image pickup device 100 having the cavity-less structure has a structure in which the light receiving surface of the semiconductor substrate 131 having the photodiodes PD arranged in a matrix and the glass substrate 134 that protects the light receiving surface of the semiconductor substrate 131 are bonded together by the resin layer 133. Note that, in the image pickup device 100 having the cavity-less structure, in order to avoid reflection of incident light from the outside at the boundary between the glass substrate 134 and the resin layer 133, the resin layer 133 preferably includes a material having a small refractive index difference from the glass substrate 134. Further, in the image pickup device 100 having the cavity-less structure, in order to effectively condense light to the photodiode PD, the on-chip lens 132 provided for each photodiode PD preferably includes a material having a refractive index higher than that of the resin layer 133.

In such a structure, as illustrated in FIG. 6A, when light is incident on the image pickup device 100, a part of the light is reflected by the light receiving surface of the semiconductor substrate 131 and reaches the boundary surface between the glass substrate 134 and the atmosphere. Further, a part of the light that has reached is reflected by the upper surface of the glass substrate 134 and is incident on the light receiving surface of the semiconductor substrate 131 again. As a result, in the image obtained by the image pickup device 100, an unnecessary flare appears due to light incident thereon again by reflection inside the image pickup device 100.

For example, as illustrated in FIG. 6B, a plurality of flares R appears at positions surrounding an image S of the incident light. The plurality of flares R constituting a ring surrounding the image S of the incident light is caused by reflected light inside the image pickup device 100, and is an image not intended to be reflected in the image. Thus, in a case where such a flare R remarkably appears, the quality of the image by the image pickup device 100 is degraded.

Here, the flare means whitish noise generated on an image due to reflection of light inside the image pickup device 100.

On the other hand, in order to avoid the occurrence of the flare R as described above, for example, the image pickup device 100 having the cavity structure as illustrated in FIG. 7A has been devised. For example, as illustrated in FIG. 7A, the image pickup device 100 having the cavity structure has a structure having a cavity 133a between the light receiving surface of the semiconductor substrate 131 including the photodiodes PD arranged in a matrix and the glass substrate 134 that protects the light receiving surface of the semiconductor substrate 131. Further, in the image pickup device 100, a resin layer 133b is provided so as to cover the outer peripheral portion of the semiconductor substrate 131 and seal the semiconductor substrate 131 and the glass substrate 134. The resin layer 133b has a function of not only sealing the image pickup device 100 but also supporting the glass substrate 134 in order to provide the cavity 133a. Note that, as described above, the inside of the cavity 133a may be filled with air, a gas such as nitrogen or argon, or may be a vacuum.

In such a structure, as illustrated in FIG. 7A, when light is incident on the image pickup device 100, a part of the light is reflected by the light receiving surface of the semiconductor substrate 131 and reaches the boundary surface between the glass substrate 134 and the atmosphere. Further, a part of the light that has reached is reflected by the upper surface of the glass substrate 134 and is directed to the light receiving surface of the semiconductor substrate 131 again. However, in the image pickup device 100 having the cavity structure, a part of the light is reflected at the boundary between the cavity 133a and the glass substrate 134 due to a refractive index difference therebetween, and thus, an amount of light again reaching the light receiving surface of the semiconductor substrate 131 decreases. Thus, as illustrated in FIG. 7B, in the image obtained by the image pickup device 100, the plurality of flares R constituting the ring surrounding the image S of the incident light does not remarkably appear.

However, in such a structure, as illustrated in FIG. 7A, in a case where the incident light from the outside is reflected by an end portion of the resin layer 133b, a part of the reflected light may be reflected at the boundary between the cavity 133a and the glass substrate 134 due to the refractive index difference therebetween, and may be incident on the light receiving surface of the semiconductor substrate 131 again. As a result, as illustrated in FIG. 7B, the light again incident on the light receiving surface generates a flare F that occurs at an image end portion separated from the image S of the incident light in the image obtained by the image pickup device 100. Such a flare F at the end portion is also caused by reflected light inside the image pickup device 100, and is an image not intended to be reflected in the image. Thus, in a case where such a flare F remarkably appears, the quality of the image by the image pickup device 100 is degraded.

Further, in the image pickup device 100 having the cavity structure, in order to support the glass substrate 134 and to avoid separation between the glass substrate 134 and the semiconductor substrate 131, the resin layer 133b is required to cover an area of, for example, about several 10% with respect to the light receiving surface of the semiconductor substrate 131.

Thus, in the image pickup device 100 having the cavity structure, there has been a limit to downsizing to a chip size level.

Thus, in view of such a situation, the present inventors have created the embodiments of the present disclosure. In the embodiments of the present disclosure created by the present inventors, a plurality of pillars (columnar bodies) is provided at the inner side from the resin layer 133b. By doing so, according to the embodiments of the present disclosure, since both are obtained of the advantages of the cavity-less structure and the advantages of the cavity structure described above, it is possible to easily perform downsizing to the chip size level while suppressing the occurrence of various flares.

Hereinafter, details of the embodiments of the present disclosure created by the present inventors will be sequentially described.

### 2. First Embodiment

### 2.1 Detailed Configuration

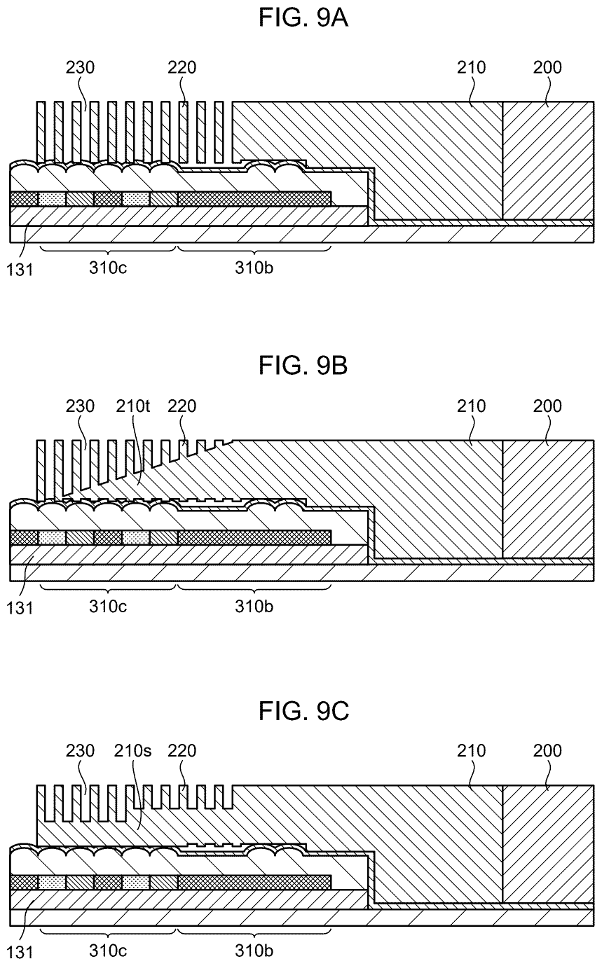

First, with reference to FIGS. 8A and 8B, a description will be given of a detailed configuration of the image pickup device 100 according to a first embodiment of the present disclosure. FIG. 8A is a plan view illustrating a structure example of the image pickup device 100 according to the present embodiment. FIG. 8B is a cross-sectional view illustrating the structure example of the image pickup device 100 according to the present embodiment, and specifically, is a cross-sectional view when the image pickup device 100 is cut along a line A-A′ illustrated in FIG. 8A.

As illustrated in FIG. 8A, the image pickup device 100 according to the present embodiment includes a sealing material (second sealing material) 200 provided along the inner side of the outer periphery of the image pickup device 100, and a sealing material (first sealing material) 210 provided at the inner side from the sealing material 200. Specifically, as illustrated in FIG. 8B, the sealing material 200 is provided on the outer periphery of the image pickup device 100 so as to cover the outer peripheral portion of the image pickup device 100, and has a role of bonding the glass substrate 134 (not illustrated in FIG. 8B) provided above the semiconductor substrate 131 and the semiconductor substrate 136 so that they are not separated from each other. In addition, as illustrated in FIG. 8B, the sealing material 210 is provided at the inner side from the sealing material 200 so as to cover at least a part of an outer peripheral portion 310 of the semiconductor substrate 131, and has a role of bonding the glass substrate 134 (not illustrated) and the semiconductor substrate 131 so as to seal them so that they are not separated from each other. The sealing materials 200 and 210 preferably include, for example, a material having a refractive index of from 1.4 to 1.6, and can include an optically transparent epoxy-based resin, low melting point glass, ultraviolet curable resin, or the like. Further, the sealing materials 200 and 210 preferably include a material that can be formed and processed at 200° C. or lower, for example. In addition, in the present embodiment, the sealing material 200 and the sealing material 210 may be formed as an integral body.

As described above, the pixel array unit 101 including the plurality of photodiodes (image pickup elements) PD arranged in an array is formed on the semiconductor substrate 131. Specifically, as illustrated in FIGS. 8A and 8B, in a central region of the pixel array unit 101, an effective pixel region 300 is arranged in which a plurality of photodiodes PD is arranged that can operate to perform image pickup. Further, on the outer periphery of the pixel array unit 101, the outer peripheral portion 310 is arranged so as to surround the effective pixel region 300. As illustrated in FIG. 8B, the outer peripheral portion 310 includes an outermost peripheral portion 310a located at the outermost periphery of the semiconductor substrate 131 and provided with no pixel 110. In addition, the outer peripheral portion 310 includes an optical black region 310b including a plurality of photodiodes PD covered with a light shielding film 420 at the inner side from the outermost peripheral portion 310a. Further, the outer peripheral portion 310 includes a non-effective pixel region 310c provided at the inner side from the optical black region 310b and provided with a photodiode PD that is covered with a color filter 410 but does not operate to perform image pickup. Furthermore, the light shielding film 420 includes, for example, a metal film of tungsten (W) or the like that does not transmit light.

Note that, in the present embodiment, the non-effective pixel region 310c may not be provided. In addition, in the present specification, the non-effective pixel region 310c and the optical black region 310b are also referred to as dummy pixel regions.

The sealing material 210 is provided so as to cover the outermost peripheral portion 310a, and further, may be provided so as to cover a part of the optical black region 310b.

Further, in the present embodiment, as illustrated in FIGS. 8A and 8B, a plurality of columnar pillars (columnar bodies) 220 is provided at the inner side from the sealing material 210. The pillars 220 are provided on a part of the outer peripheral portion 310 of the semiconductor substrate 131, and specifically, are provided on a part of the optical black region 310b. In addition, the pillars 220 may be provided on a part of the outermost peripheral portion 310a, and further, may be provided on the non-effective pixel region 310c.

Each pillar 220 preferably includes a material having a refractive index of from 1.4 to 1.6 (high refractive index material), and specifically, for example, similarly to the sealing materials 200 and 210, can include an optically transparent epoxy-based resin, low melting point glass, ultraviolet curable resin, or the like. In addition, the pillar 220 may include the same material as the sealing materials 200 and 210. Further, the side surface of the pillar 220 may be subjected to surface roughening in order to suppress reflection. Furthermore, in the present embodiment, the area of the pillar 220 in a plan view is preferably smaller than 10 times the size of the photodiode PD in a plan view.

In addition, a gap 230 between the pillars 220 adjacent to each other may be a vacuum, or may be filled with a gas such as air, nitrogen, or argon. Further, the gap 230 may be filled with a material having a refractive index lower than that of the pillar 220, for example, a resin having a refractive index of from 1.3 to 1.4.

Further, in the present embodiment, there is a cavity (gap) 240 between the effective pixel region 300 of the semiconductor substrate 131 and the glass substrate 134 (not illustrated). In addition, the cavity 240 may be a vacuum, or may be filled with a gas such as air, nitrogen, or argon. Furthermore, in the present embodiment, the cavity 240 may be filled with a resin having a refractive index lower than that of the pillar 220. Specifically, the cavity 240 may be filled with, for example, a resin (low refractive index material) having a refractive index of from 1.3 to 1.4.

In the present embodiment, since light is reflected at the boundary between the cavity 240 and the glass substrate 134 due to the presence of the cavity 240 on the effective pixel region 300, reflected light in the image pickup device 100 does not reach the light receiving surface of the semiconductor substrate 131 again. Thus, in the present embodiment, similarly to the cavity structure described above, it is possible to avoid the occurrence of the plurality of flares R that constitutes the ring surrounding the image S of the incident light and may occur in the cavity-less structure described above.

Further, in the present embodiment, even in a case where the incident light from the outside travels to an inner end portion of the sealing material 210, the incident light is irregularly reflected complicatedly due to the presence of the plurality of pillars 220 before reaching the inner end portion of the sealing material 210. Thus, in the present embodiment, since light is less likely to be uniformly reflected at the inner end portion of the sealing material 210, it is possible to avoid the occurrence of the flare F that occurs at the image end portion and may occur in the cavity structure.

Further, in the image pickup device 100 having the cavity structure described above, in order to avoid separation between the glass substrate 134 and the semiconductor substrate 131, the resin layer 133b is required to cover an area of a predetermined size or more with respect to the light receiving surface of the semiconductor substrate 131. However, in the present embodiment, by providing the plurality of pillars 220, it is possible to suppress separation between the glass substrate 134 and the semiconductor substrate 131, so that the area covered by the sealing material 210 can be reduced. Thus, according to the present embodiment, similarly to the cavity-less structure, the image pickup device 100 can be easily downsized to a chip size level.

That is, in the present embodiment, since both are obtained of the advantages of the cavity-less structure and the advantages of the cavity structure described above, it is possible to easily perform downsizing to the chip size level while suppressing the occurrence of various flares.

### 2.2 First Modification

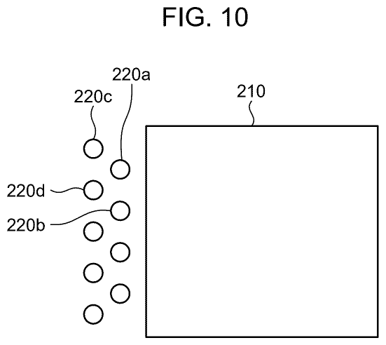

Next, with reference to FIG. 9, a description will be given of a detailed configuration of the image pickup device 100 according to a first modification of the present embodiment. FIG. 9 is a cross-sectional view illustrating a structure example of the image pickup device 100 according to the first modification of the present embodiment.

The present embodiment is not limited to the structure in which the pillars 220 are directly provided on the semiconductor substrate 131 as illustrated in FIG. 9A. For example, as illustrated in FIGS. 9B and 9C, the sealing material 210 may be extended and provided to a part of the optical black region 310b or the non-effective pixel region 310c of the semiconductor substrate 131. The pillars 220 may be provided on a portion where the sealing material 210 is extended.

Specifically, as illustrated in FIG. 9B, the sealing material 210 includes an extended portion 210t extending on a part of the optical black region 310b and the non-effective pixel region 310c. In addition, the upper surface of the extended portion 210t is formed to be a slope in which the upper surface becomes higher at a position closer to the outer side of the image pickup device 100. Further, the plurality of pillars 220 is provided on the upper surface of the extended portion 210t.

In addition, as illustrated in FIG. 9C, the sealing material 210 includes an extended portion 210s extending on a part of the optical black region 310b and the non-effective pixel region 310c. Further, the upper surface of the extended portion 210s is formed to have a staircase structure in which the upper surface becomes higher at a position closer to the outer side of the image pickup device 100. Furthermore, the plurality of pillars 220 is provided on the upper surface of the extended portion 210s.

As described above, in the present modification, by modifying the shape and the like of the inner end portion of the sealing material 210, it is possible to irregularly reflect light effectively by the plurality of pillars 220 and the inner end portion of the sealing material 210. Thus, in the present modification, it is possible to further avoid the occurrence of the flare F that occurs at the image end portion.

### 2.3 Second modification

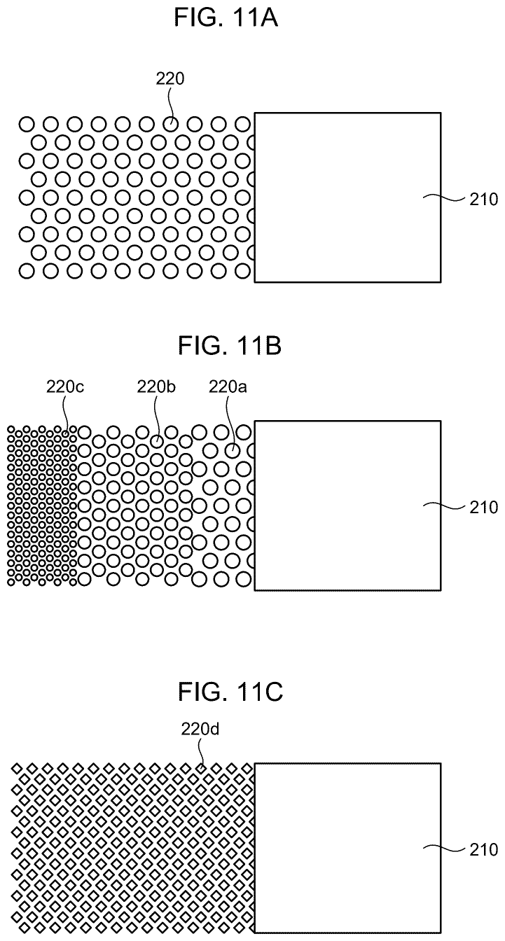

Next, with reference to FIGS. 10 to 12, a description will be given of a detailed configuration of the image pickup device 100 according to a second modification of the present embodiment. FIGS. 10 to 12 are plan views each illustrating a structure example of the image pickup device 100 according to the second modification of the present embodiment, and specifically, are enlarged views of a region B illustrated in FIG. 8A.

In the present modification, as illustrated in FIG. 10, the plurality of pillars 220 is preferably provided in a checkered pattern in a plan view. By doing so, even if the incident light from the outside is reflected by the inner end portion of the sealing material 210, the incident light reaches any of the side surfaces of the plurality of pillars 220 without leakage and is irregularly reflected complicatedly. Thus, in the present modification, since light is less likely to be uniformly reflected at the inner end portion of the sealing material 210, it is possible to further avoid the occurrence of the flare F that occurs at the image end portion and may occur in the cavity structure.

Specifically, in the present modification, as illustrated in FIG. 10, the plurality of pillars 220 includes, for example, a pillar (first columnar body) 220a, a pillar (second columnar body) 220b, a pillar (third columnar body) 220c, and a pillar (fourth columnar body) 220d. In a plan view, the pillars 220a and 220b are arranged at predetermined intervals along the vertical direction (first direction) in the drawing. In addition, the pillars 220c and 220d are also arranged at predetermined intervals along the vertical direction (predetermined direction) in the drawing. Further, a row (first row) including the pillars 220a and 220b and a row (second row) including the pillars 220c and 220d are adjacent to each other along the left-right direction (second direction) in the drawing. Furthermore, in the vertical direction in the drawing, the pillar 220a is located between the pillar 220c and the pillar 220d. That is, in the present modification, as illustrated in FIG. 10, in a case where a plurality of adjacent rows is viewed from the inner end portion of the sealing material 210, the pillars 220 in different rows are alternately arranged so that one pillar 220 in one row appears to be arranged between two pillars 220 in the other row.

Note that, in the present modification, it is preferable that there are two or more rows formed by arranging the plurality of pillars 220 in a row along each side of the effective pixel region 300.

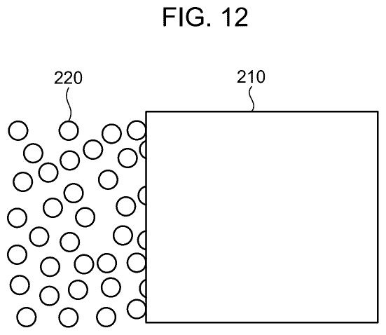

In addition, in the present modification, as illustrated in FIG. 11A, the plurality of pillars 220 is not limited to the same size. For example, as illustrated in FIG. 11B, the cross-sectional area of the pillar 220 may be sequentially reduced as the pillar 220 is closer to the effective pixel region 300. Specifically, in FIG. 11B, the pillar 220a closest to the sealing material 210 is the largest, the pillar 220c closest to the effective pixel region 300 is the smallest, and the pillar 220b located between the pillar 220a and the pillar 220c is smaller than the pillar 220a and larger than the pillar 220c.

As described above, in the present modification, by changing the cross-sectional area of the pillar 220 according to a relative position with respect to the effective pixel region 300, it is possible for the plurality of pillars 220, particularly, the pillars 220 at positions close to the effective pixel region 300 to irregularly reflect light effectively. Thus, in the present modification, it is possible to further avoid the occurrence of the flare F that occurs at the image end portion.

Further, the modification is not limited to the substantially circular cross section of the pillar 220 as illustrated in FIG. 11A. For example, as illustrated in FIG. 11C, the pillar 220d may have a substantially polygonal (substantially rectangular in FIG. 11C) cross section. Further, in a case where the cross section of the pillar 220 has a polygonal shape, it is preferable that the vertex of the corner of the polygonal shape is directed toward the center of the effective pixel region 300. By doing so, the light reflected by the side surface of the pillar 220 is irregularly reflected in a direction other than the direction toward the center of the effective pixel region 300. As a result, according to the present modification, it is possible to avoid that the reflected light reaches the effective pixel region 300 again, and avoid the occurrence of the flares.

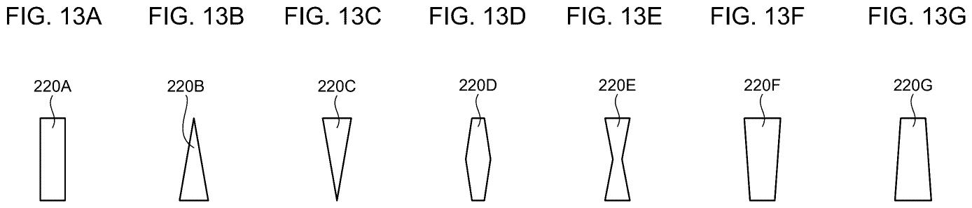

Further, the present modification is not limited to the regular arrangement of the pillars 220 as described above, and the pillars 220 may be randomly arranged in a plan view as illustrated in FIG. 12. Even in this case, it is preferable that two or more of the plurality of pillars 220 are arranged along each side of the effective pixel region 300. Further, also in the present modification, in a case where a plurality of adjacent pillars 220 is viewed from the inner end portion of the sealing material 210, it is preferable that the pillars 220 are alternately arranged so that, between two adjacent pillars 220 substantially equidistant from the inner end portion of the sealing material 210, one pillar 220 having a different distance from the inner end portion of the sealing material 210 appears to be arranged. By doing so, even if the incident light from the outside is reflected by the inner end portion of the sealing material 210, the incident light reaches any of the side surfaces of the plurality of pillars 220 without leakage and is irregularly reflected complicatedly. Thus, also in the present modification, since light is less likely to be uniformly reflected at the inner end portion of the sealing material 210, it is possible to further avoid the occurrence of the flare F that occurs at the image end portion and may occur in the cavity structure.

### 2.4 Third modification

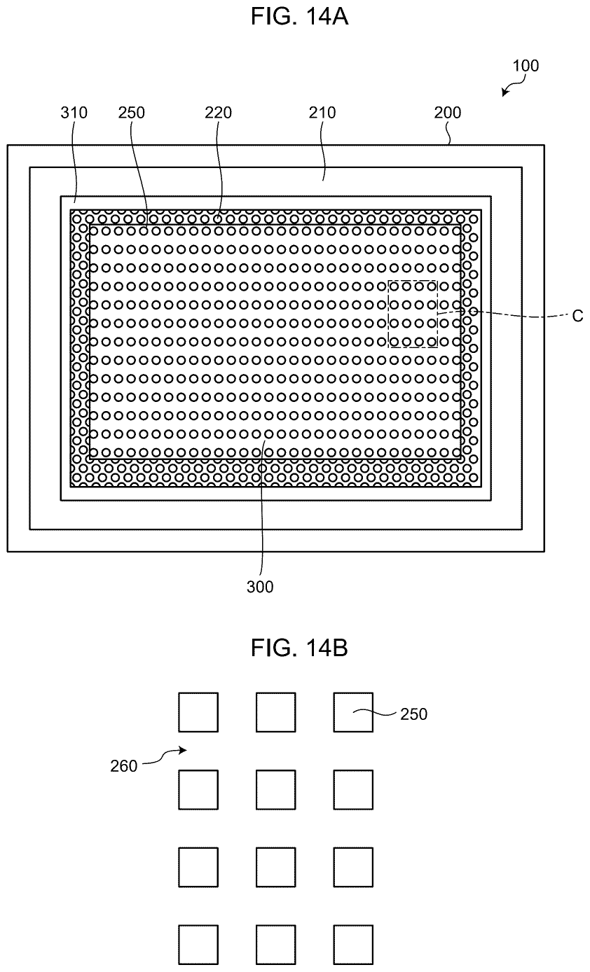

Next, a detailed configuration of the pillar 220 according to a third modification of the present embodiment will be described with reference to FIG. 13. FIG. 13 is a cross-sectional view illustrating a structure example of the pillar 220 according to the third modification of the present embodiment, and specifically illustrates a cross section when the pillar 220 is cut along a stacking direction of the image pickup device 100.

In the embodiments of the present disclosure, the pillar 220 is not limited to a substantially cylindrical or substantially prismatic column having a rectangular cross section like a pillar 220A illustrated in A of FIG. 13.

For example, as illustrated in FIG. 13B, the pillar 220 may be a pillar 220B that has a substantially conical or substantially pyramidal shape having a cross section having a vertex upward (specifically, toward the glass substrate 134). In addition, for example, as illustrated in FIG. 13C, the pillar 220 may be a pillar 220C that has a substantially conical or substantially pyramidal shape having a cross section having a vertex downward (specifically, toward the semiconductor substrate 131).

In addition, as illustrated in FIGS. 13D and 13E, the pillars 220 may be pillars 220D and 220E having a shape in which two substantially conical or substantially pyramidal shapes whose vertexes are cut are stacked.

Specifically, as illustrated in FIG. 13D, the pillar 220 may be the pillar 220D in which two substantially conical or substantially pyramidal shapes are stacked such that the vertexes before being cut face outward. Alternatively, as illustrated in FIG. 13E, the pillar 220 may be the pillar 220E in which two substantially conical or substantially pyramidal shapes are stacked such that the vertexes before being cut face inward.

Further, as illustrated in FIGS. 13F and 13G, the pillars 220 may be pillars 220F and 220G having a substantially conical or substantially pyramidal shape whose vertex is cut. Specifically, as illustrated in FIG. 13F, the pillar 220 may be the pillar 220F having a shape in which the vertex is cut of a substantially conical or substantially pyramidal shape having the vertex downward (specifically, toward the semiconductor substrate 131).

Alternatively, as illustrated in FIG. 13G, the pillar 220 may be the pillar 220G having a shape in which the vertex is cut of a substantially conical or substantially pyramidal shape having the vertex upward (specifically, toward the glass substrate 134).

In the present modification, by modifying the shape of the pillar 220 in this manner, it is possible to irregularly reflect light more complicatedly. Thus, also in the present modification, since light is less likely to be uniformly reflected at the inner end portion of the sealing material 210, it is possible to further avoid the occurrence of the flare F that occurs at the image end portion and may occur in the cavity structure.

Note that, in the present embodiment, the image pickup device 100 is not limited to the structure illustrated in FIGS. 8A to 13.

### 3. Second embodiment

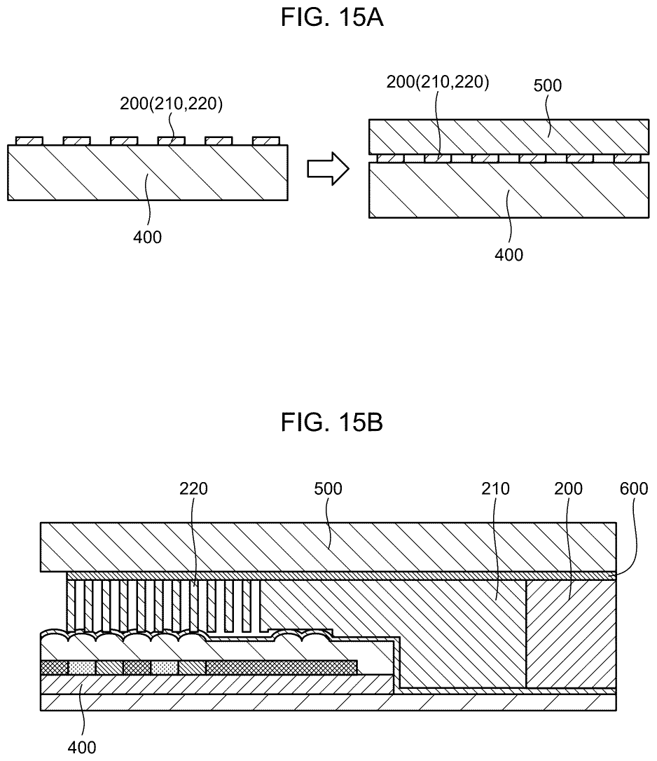

Next, with reference to FIGS. 14A and 14B, a description will be given of a detailed configuration of the image pickup device 100 according to a second embodiment of the present disclosure. FIG. 14A is a plan view illustrating a structure example of the image pickup device 100 according to the present embodiment. FIG. 14B is an enlarged view illustrating the structure example of the image pickup device 100 according to the present embodiment, and specifically, is an enlarged view of a region C illustrated in FIG. 14A.

In the present embodiment, unlike the first embodiment described above, the cavity 240 may not be uniformly provided over the entire effective pixel region 300, but a cavity 260 may be provided only on specific photodiodes PD in the effective pixel region 300, and a resin layer 250 may be provided on other photodiodes PD in the effective pixel region 300.

Specifically, in the present embodiment, as illustrated in FIGS. 14A and 14B, there is the cavity (gap) 260 above the specific photodiodes PD in the effective pixel region 300 between the effective pixel region 300 and the glass substrate 134 (not illustrated). In addition, the cavity 260 may be a vacuum, or may be filled with a gas such as air, nitrogen, or argon.

Further, in the present embodiment, the resin layer 250 is provided on the remaining photodiodes PD in the effective pixel region 300 between the effective pixel region 300 and the glass substrate 134 (not illustrated).

The resin layer 250 preferably includes a material having the same refractive index as that of the pillar 220 or a material having a refractive index lower than that of the pillar 220, for example, a resin having a refractive index of from 1.3 to 1.4. In addition, the on-chip lens 132 for the photodiode PD located below the resin layer 250 preferably includes a material having a refractive index higher than that of the resin layer 250. For example, in a case where the resin layer 250 has a refractive index lower than that of the pillar 220, specifically, in the case of a resin having a refractive index of from 1.3 to 1.4, the on-chip lens 132 preferably includes a material having a refractive index of from 1.4 to 1.6. In addition, for example, in a case where the resin layer 250 is a resin having a refractive index of from 1.3 to 1.4 and in a case where the resin layer 250 is a material having the same refractive index as that of the pillar 220, the on-chip lens 132 can include silicon nitride or the like. Further, as the resin layer 250 itself, a wavelength conversion film that converts X-rays into visible light or converts infrared light into visible light may be introduced, and by doing so, it is possible to expand a wavelength range of light that can be detected by the image pickup device 100.

As described above, in the present embodiment, by providing the resin layer 250 also on a part of the effective pixel region 300, it is possible to further strengthen the bonding between the glass substrate 134 and the semiconductor substrate 131. As a result, in the present embodiment, the image pickup device 100 can be easily downsized to a chip size level.

Note that, in the present embodiment, the image pickup device 100 is not limited to the structure illustrated in FIGS. 14A and 14B.

### 4. Third Embodiment

### 4.1 First Example of Manufacturing Method

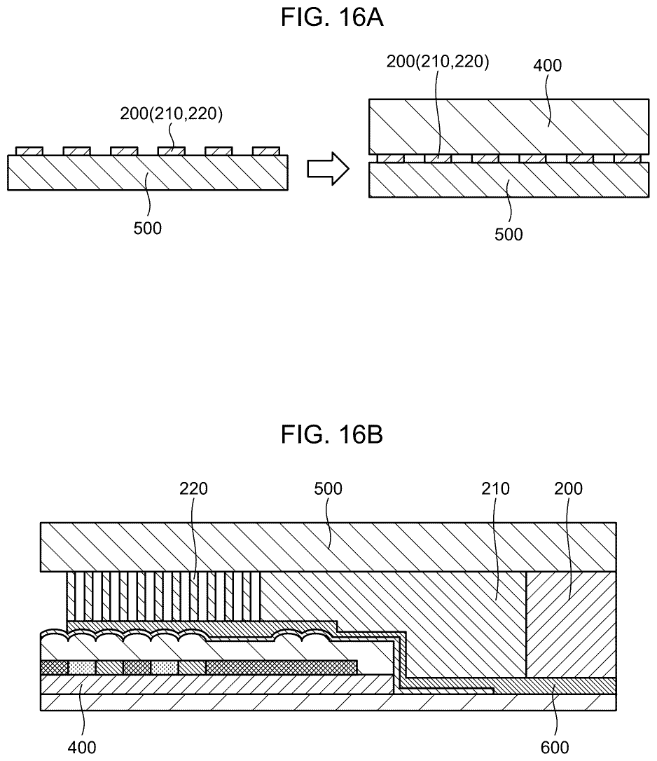

First, a first example of a manufacturing method for the image pickup device 100 will be described as a third embodiment of the present disclosure with reference to FIGS. 15A and 15B. FIGS. 15A and 15B are process cross-sectional views illustrating the first example of the manufacturing method for the image pickup device 100 according to the present embodiment.

In the present embodiment, as illustrated on the left side of FIG. 15A, the sealing materials 200 and 210 and the pillar 220 on a semiconductor substrate 400 are patterned by use of a method such as photolithography. At this time, the pillar 220 is processed into a desired shape by use of photolithography and etching.

Then, as illustrated on the right side of FIG. 15A, a glass substrate 500 is bonded onto the patterned sealing materials 200 and 210 and the pillar 220. The bonding can be performed by thermocompression bonding or use of an adhesive 600. Then, a structure as illustrated in FIG. 15B can be obtained.

### 4.2 Second Example of Manufacturing Method

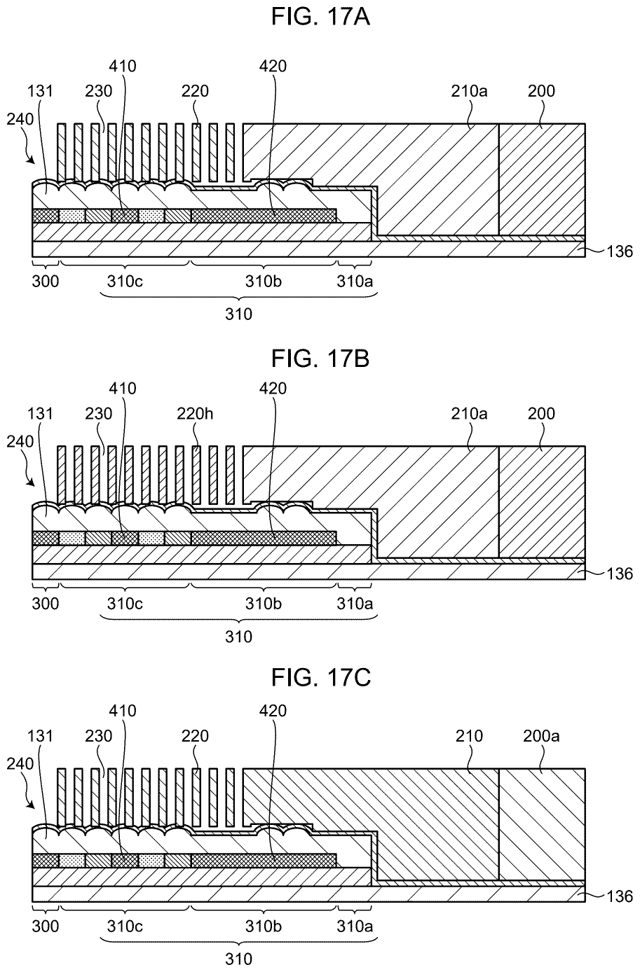

Next, a second example of the manufacturing method for the image pickup device 100 will be described with reference to FIGS. 16A and 16B. FIGS. 16A and 16B are process cross-sectional views illustrating the second example of the manufacturing method for the image pickup device 100 according to the present embodiment.

In the present embodiment, as illustrated on the left side of FIG. 16A, the sealing materials 200 and 210 and the pillar 220 on the glass substrate 500 are patterned by use of a method such as photolithography. At this time, the pillar 220 is processed into a desired shape by use of photolithography and etching. Note that it is not limited to providing all of the sealing materials 200 and 210 and the pillar 220 on the glass substrate 500, and for example, only the sealing material 200 may be provided on the glass substrate 500, and the sealing material 210 and the pillar 220 may be provided on the semiconductor substrate 400.

Then, as illustrated on the right side of FIG. 15A, the semiconductor substrate 400 is bonded onto the patterned sealing materials 200 and 210 and the pillar 220. The bonding can be performed by thermocompression bonding or use of the adhesive 600. Then, a structure as illustrated in FIG. 16B can be obtained.

Note that, in the present embodiment, the manufacturing method for the image pickup device 100 is not limited to the manufacturing method described with reference to FIGS. 15A to 16B.

### 5. Fourth Embodiment

### 5.1 Detailed Configuration

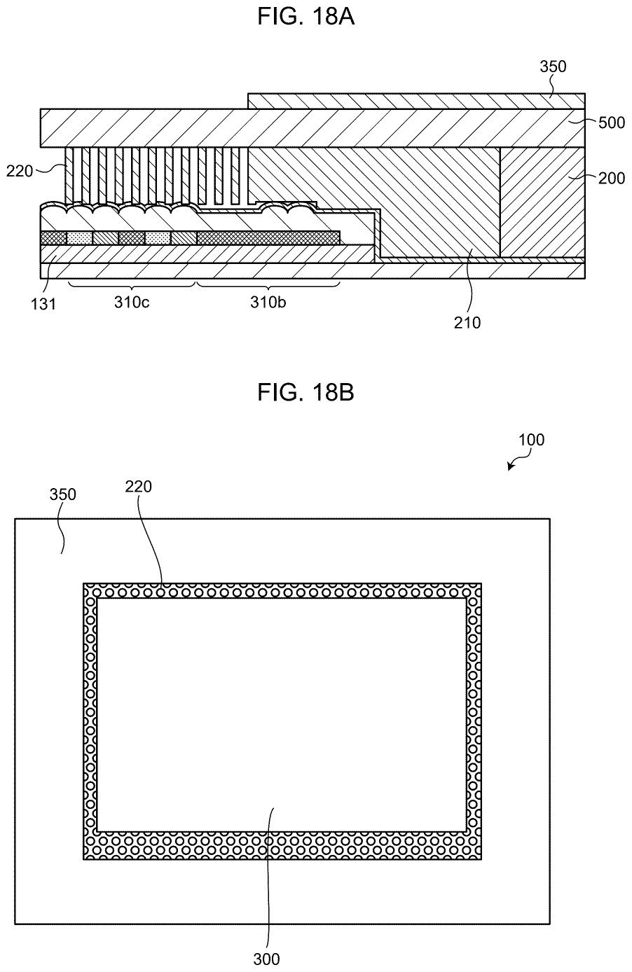

Next, with reference to FIG. 17, a description will be given of a detailed configuration of the image pickup device 100 according to a fourth embodiment of the present disclosure. FIG. 17 is a cross-sectional view illustrating a structure example of the image pickup device 100 according to the present embodiment. In the present embodiment, by devising the materials of the sealing materials 200 and 210 and the pillar 220, it is possible to further suppress the occurrence of the flares.

In the present embodiment, for example, as illustrated in the upper part (A) of FIG. 17, a light absorbing material that absorbs light having a wavelength within a predetermined wavelength band may be included only in a sealing material 210a. Alternatively, in the present embodiment, for example, as illustrated in the middle part (B) of FIG. 17, the light absorbing material that absorbs the light having the wavelength within the predetermined wavelength band may be included in a pillar 220h and the sealing material 210a. Further, in the present embodiment, for example, as illustrated in the lower part (C) of FIG. 17, the light absorbing material that absorbs the light having the wavelength within the predetermined wavelength band may be included in a sealing material 200a.

Furthermore, in the present embodiment, although not illustrated, the light absorbing material that absorbs the light having the wavelength within the predetermined wavelength band may be included in the sealing materials 200a and 210a, or the light absorbing material that absorbs the light having the wavelength within the predetermined wavelength band may be included in the sealing material 200a and the pillar 220h.

In the present embodiment, the light absorbing material may be a material that absorbs light having a wavelength within the visible light band, or may be a material that absorbs light having a wavelength within the infrared light band. More specifically, in the present embodiment, the material that absorbs the light having the wavelength within the visible light band may include, for example, carbon black, titanium black, or a mixture thereof. In the present embodiment, the material that absorbs the light having the wavelength within the infrared light band may include, for example, lanthanum hexaboride (LaB₆), cesium-doped tungsten oxide (CWO), or a mixture thereof.

In addition, in the present embodiment, a plurality of the pillars 220h is not limited to having the same size as in the embodiments and the modifications described above, and may have different sizes. Further, in the present embodiment, the pillar 220h is not limited to having a substantially circular cross section (a cross section obtained by cutting of the pillar 220h in parallel to a plane of the semiconductor substrate 131), and may have, for example, a substantially polygonal cross section. Furthermore, in the present embodiment, the arrangement of the pillars 220h is not limited to being regular, and the pillars 220h may be randomly arranged in a plan view.

Further, in the present embodiment, the cross section when the pillar 220h is cut along the film thickness direction of the semiconductor substrate 131 is not limited to a substantially cylindrical or substantially prismatic column having a rectangular cross section. For example, the cross section of the pillar 220h may be a substantially conical or substantially pyramidal shape having a cross section having a vertex upward, or may be a substantially conical or substantially pyramidal shape having a cross section having a vertex downward.

Furthermore, for example, the pillar 220h may have a shape in which two substantially conical or substantially pyramidal shapes whose vertexes are cut are stacked, or may have a shape in which two substantially conical or substantially pyramidal shapes are stacked such that the vertexes before being cut face inward. In addition, for example, the pillar 220h may have a substantially conical or substantially pyramidal shape in which the vertex is cut, or may have a shape in which the vertex is cut of a substantially conical or substantially pyramidal shape having the vertex upward.

As described above, in the present embodiment, by formation of the materials of the sealing materials 200 and 210 and the pillar 220 using the light absorbing material that absorbs the light having the wavelength within the predetermined wavelength band, even in a case where incident light from the outside travels to the inner end portion of the sealing material 210a, the incident light is uniformly absorbed by the plurality of pillars 220h before reaching the inner end portion of the sealing material 210a. Further, in the present embodiment, light not absorbed by the pillars 220h is also absorbed by the sealing materials 210a and 200a. Thus, in the present embodiment, since light is less likely to be uniformly reflected at the inner end portions of the sealing materials 210a and 200a, it is possible to avoid the occurrence of the flare F that occurs at the image end portion and may occur in the cavity structure.

In addition, the manufacturing method for the image pickup device 100 according to the present embodiment conforms to the third embodiment of the present disclosure described above. Thus, the present embodiment can be implemented without significant change of a manufacturing process of the image pickup device 100.

### 5.2 First Modification

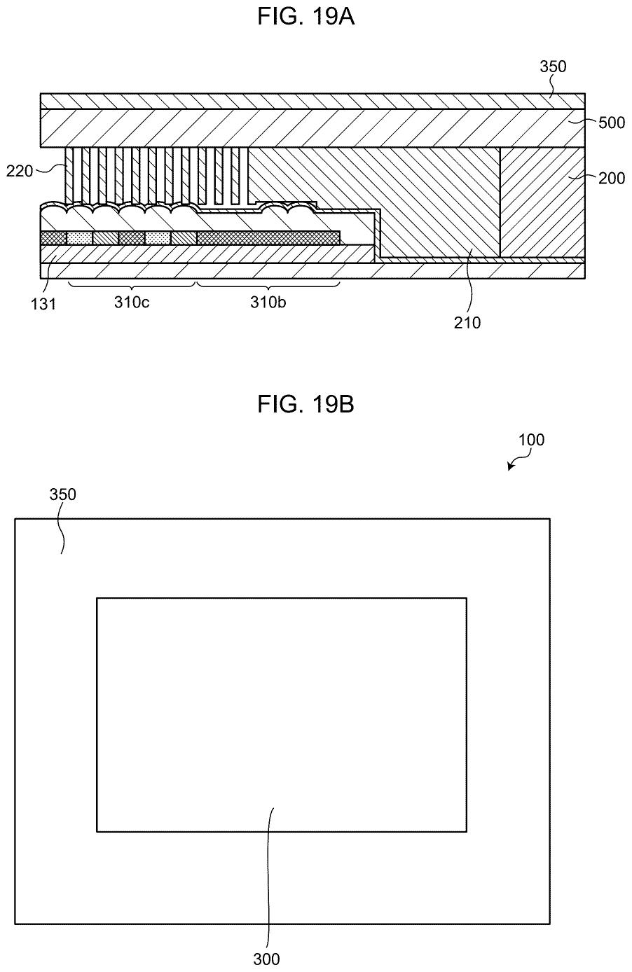

Next, with reference to FIGS. 18A and 18B, a description will be given of a detailed configuration of the image pickup device 100 according to a first modification of the present embodiment. FIG. 18A is a cross-sectional view illustrating a structure example of the image pickup device 100 according to the first modification of the present embodiment, and FIG. 18B is a plan view illustrating the structure example of the image pickup device 100 according to the first modification of the present embodiment.

As illustrated in FIGS. 18A and 18B, in the image pickup device 100 according to the present first modification, a light absorbing layer 350 including the light absorbing material that absorbs the light having the wavelength within the predetermined wavelength band is provided in a region located above the sealing material 200 provided on the outer periphery of the image pickup device 100 so as to cover the outer peripheral portion of the image pickup device 100 and the sealing material 210 provided so as to cover a part of the outer peripheral portion 310 of the semiconductor substrate 131, of the upper surface of the glass substrate 500 provided above the semiconductor substrate 131.

Also in the first modification, the light absorbing material may be the material that absorbs the light having the wavelength within the visible light band, or may be the material that absorbs the light having the wavelength within the infrared light band. More specifically, also in the present first modification, the material that absorbs the light having the wavelength within the visible light band may include, for example, carbon black, titanium black, or a mixture thereof. Also in the first modification, the material that absorbs the light having the wavelength within the infrared light band may include, for example, lanthanum hexaboride, cesium-doped tungsten oxide, or a mixture thereof.

As described above, in the present first modification, by formation of the light absorbing layer 350 on a part of the upper surface of the glass substrate 500, light is not reflected at the boundary of the glass substrate 500, and reflected light in the image pickup device 100 does not reach the light receiving surface of the semiconductor substrate 131 again. Thus, in the first modification, similarly to the cavity structure described above, it is possible to avoid the occurrence of the plurality of flares R that constitutes the ring surrounding the image S of the incident light and may occur in the cavity-less structure described above. In addition, the manufacturing method for the image pickup device 100 according to the first modification can use the manufacturing method of the third embodiment of the present disclosure described above by forming the light absorbing layer 350 in advance on a part of the upper surface of the glass substrate 500. Thus, the present first modification can be implemented without significant change of the manufacturing process of the image pickup device 100.

### 5.3 Second Modification

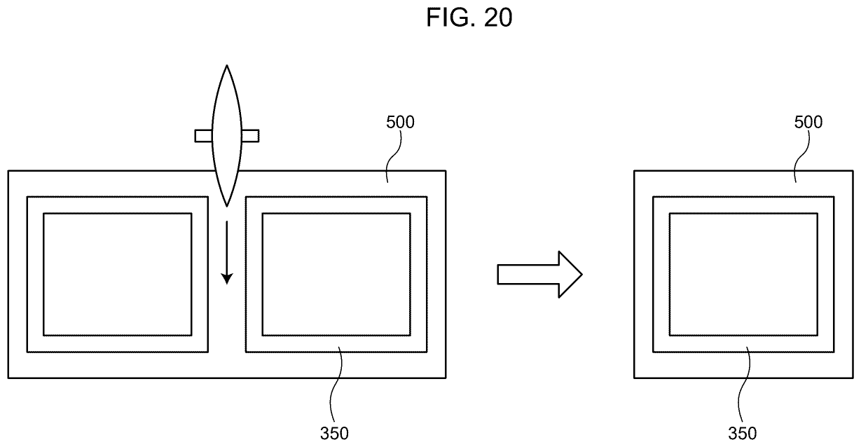

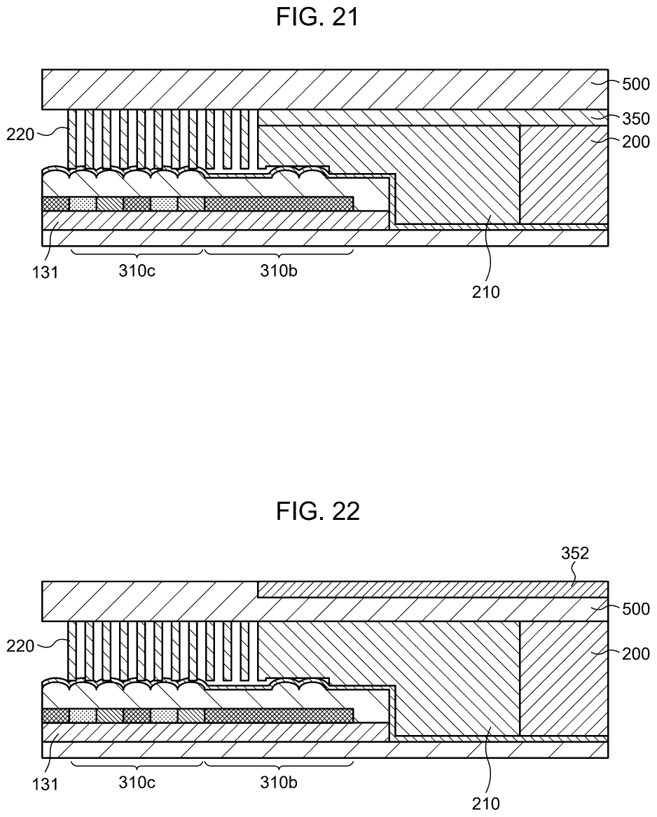

Next, with reference to FIGS. 19A, 19B, and 20, a description will be given of a detailed configuration of the image pickup device 100 according to a second modification of the present embodiment. FIG. 19A is a cross-sectional view illustrating a structure example of the image pickup device 100 according to the second modification of the present embodiment, and FIG. 19B is a plan view illustrating the structure example of the image pickup device 100 according to the second modification of the present embodiment. Further, FIG. 20 is an explanatory diagram for explaining the first and second modifications of the present embodiment.

As illustrated in FIGS. 19A and 19B, in the image pickup device 100 according to the present second modification, the light absorbing layer 350 including the light absorbing material that absorbs the light having the wavelength within the predetermined wavelength band is provided in a region located above the sealing material 200 provided on the outer periphery of the image pickup device 100 so as to cover the outer peripheral portion of the image pickup device 100 and the sealing material 210 provided so as to cover a part of the outer peripheral portion 310 of the semiconductor substrate 131, of the upper surface of the glass substrate 500 provided above the semiconductor substrate 131. Further, in the present second modification, the light absorbing layer 350 extends to a portion located above the pillars 220 of the non-effective pixel region 310c that is a dummy pixel region, of the upper surface of the glass substrate 500. That is, as illustrated in FIG. 19B in a plan view, the width of the light absorbing layer 350 is wider than that of the first modification.

Also in the second modification, the light absorbing material may be the material that absorbs the light having the wavelength within the visible light band, or may be the material that absorbs the light having the wavelength within the infrared light band. More specifically, also in the present second modification, the material that absorbs the light having the wavelength within the visible light band may include, for example, carbon black, titanium black, or a mixture thereof. Also in the second modification, the material that absorbs the light having the wavelength within the infrared light band may include, for example, lanthanum hexaboride, cesium-doped tungsten oxide, or a mixture thereof.

Note that, in the first modification and the second modification, as illustrated in FIG. 20, in order to avoid influence of the formation of the light absorbing layer 350 on the glass substrate 500 on processing of alignment and dicing, it is preferable not to form the light absorbing layer 350 on the dicing line.

As described above, also in the present second modification, by formation of the light absorbing layer 350 on a part of the upper surface of the glass substrate 500, light is not reflected at the boundary of the glass substrate 500, and reflected light in the image pickup device 100 does not reach the light receiving surface of the semiconductor substrate 131 again. Thus, in the second modification, similarly to the cavity structure described above, it is possible to avoid the occurrence of the plurality of flares R that constitutes the ring surrounding the image S of the incident light and may occur in the cavity-less structure described above. In addition, the manufacturing method for the image pickup device 100 according to the second modification can use the manufacturing method of the third embodiment of the present disclosure described above by forming the light absorbing layer 350 in advance on a part of the upper surface of the glass substrate 500. Thus, the present second modification can be implemented without significant change of the manufacturing process of the image pickup device 100.

### 5.4 Third Modification

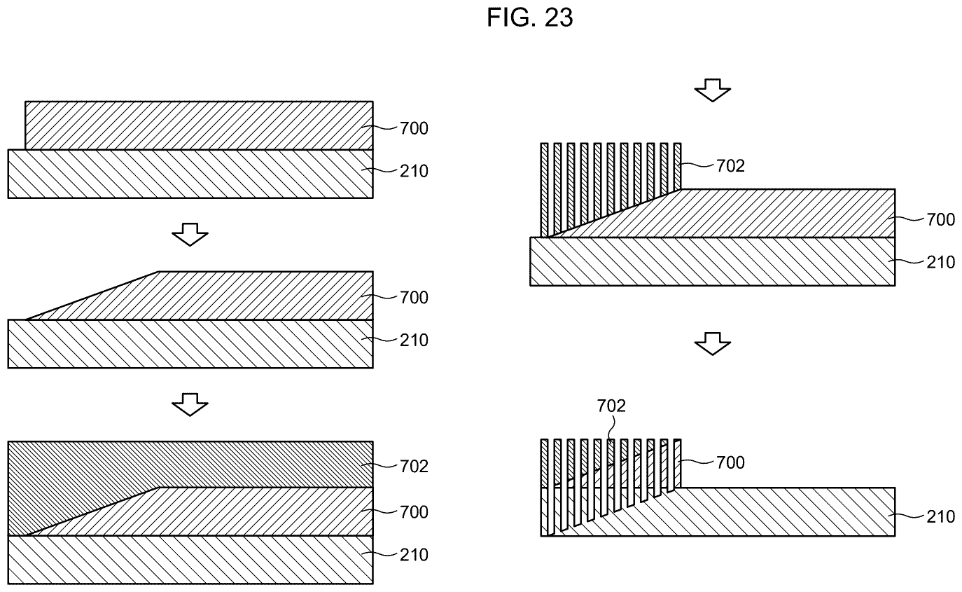

Next, with reference to FIG. 21, a description will be given of a detailed configuration of the image pickup device 100 according to a third modification of the present embodiment. FIG. 21 is a cross-sectional view illustrating a structure example of the image pickup device 100 according to the third modification of the present embodiment.

As illustrated in FIG. 21, in the image pickup device 100 according to the present third modification, the light absorbing layer 350 including the light absorbing material that absorbs the light having the wavelength within the predetermined wavelength band is provided in a region located above the sealing material 200 provided on the outer periphery of the image pickup device 100 so as to cover the outer peripheral portion of the image pickup device 100 and the sealing material 210 provided so as to cover a part of the outer peripheral portion 310 of the semiconductor substrate 131, of the lower surface of the glass substrate 500 provided above the semiconductor substrate 131 and facing the semiconductor substrate 131.

Note that, also in the present third modification, the light absorbing layer 350 may extend to a portion located above the pillars 220 in the non-effective pixel region 310c that is a dummy pixel region, of the lower surface of the glass substrate 500.

Also in the third modification, the light absorbing material may be the material that absorbs the light having the wavelength within the visible light band, or may be the material that absorbs the light having the wavelength within the infrared light band. More specifically, also in the third modification, the material that absorbs the light having the wavelength within the visible light band may include, for example, carbon black, titanium black, or a mixture thereof. Also in the third modification, the material that absorbs the light having the wavelength within the infrared light band may include, for example, lanthanum hexaboride, cesium-doped tungsten oxide, or a mixture thereof.

As described above, also in the present third modification, by formation of the light absorbing layer 350 on a part of the lower surface of the glass substrate 500, light is not reflected at the boundary of the glass substrate 500, and reflected light in the image pickup device 100 does not reach the light receiving surface of the semiconductor substrate 131 again. Thus, in the third modification, similarly to the cavity structure described above, it is possible to avoid the occurrence of the plurality of flares R that constitutes the ring surrounding the image S of the incident light and may occur in the cavity-less structure described above. In addition, the manufacturing method for the image pickup device 100 according to the third modification can use the manufacturing method of the third embodiment of the present disclosure described above by forming the light absorbing layer 350 in advance on a part of the lower surface of the glass substrate 500. Thus, the present third modification can be implemented without significant change of the manufacturing process of the image pickup device 100.

### 5.5 Fourth Modification

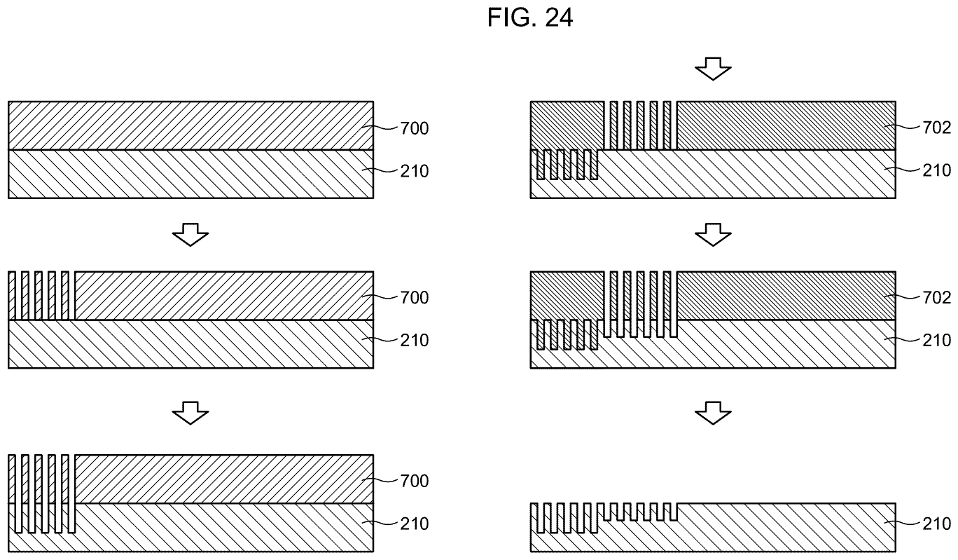

Next, with reference to FIG. 22, a description will be given of a detailed configuration of the image pickup device 100 according to a fourth modification of the present embodiment. FIG. 22 is a cross-sectional view illustrating a structure example of the image pickup device 100 according to the fourth modification of the present embodiment.

As illustrated in FIG. 22, in the image pickup device 100 according to the present fourth modification, a rough surface 352 subjected to surface roughening for irregularly reflecting light may be provided in a region located above the sealing material 200 provided on the outer periphery of the image pickup device 100 so as to cover the outer peripheral portion of the image pickup device 100 and the sealing material 210 provided so as to cover a part of the outer peripheral portion 310 of the semiconductor substrate 131, of the upper surface of the glass substrate 500 provided above the semiconductor substrate 131. In the present fourth modification, for example, the rough surface 352 can be a surface that has been processed to become a frosted glass surface.

Specifically, examples of a method of processing to obtain the frosted glass surface include chemical treatment with a chemical solution such as hydrofluoric acid (HF), and physical treatment by performing half-cutting processing using a thick blade at the time of dicing.

Note that, in the present fourth modification, the rough surface 352 may extend to a portion located above the pillars 220 in the non-effective pixel region 310c that is a dummy pixel region, of the upper surface of the glass substrate 500.

As described above, in the present fourth modification, by provision of the rough surface 352 that irregularly reflects light on a part of the upper surface of the glass substrate 500, light is not reflected at the boundary of the glass substrate 500, and reflected light in the image pickup device 100 does not reach the light receiving surface of the semiconductor substrate 131 again. Thus, in the fourth modification, similarly to the cavity structure described above, it is possible to avoid the occurrence of the plurality of flares R that constitutes the ring surrounding the image S of the incident light and may occur in the cavity-less structure described above. In addition, the manufacturing method for the image pickup device 100 according to the fourth modification can use the manufacturing method of the third embodiment of the present disclosure described above by forming the light absorbing layer 350 in advance on a part of the upper surface of the glass substrate 500. Thus, the present fourth modification can be implemented without significant change of the manufacturing process of the image pickup device 100.

Note that, in the present embodiment and the modifications, the image pickup device 100 is not limited to the structure and form illustrated in FIGS. 17 to 22.

### 6. Fifth Embodiment

### 6.1 First Example of Manufacturing Method

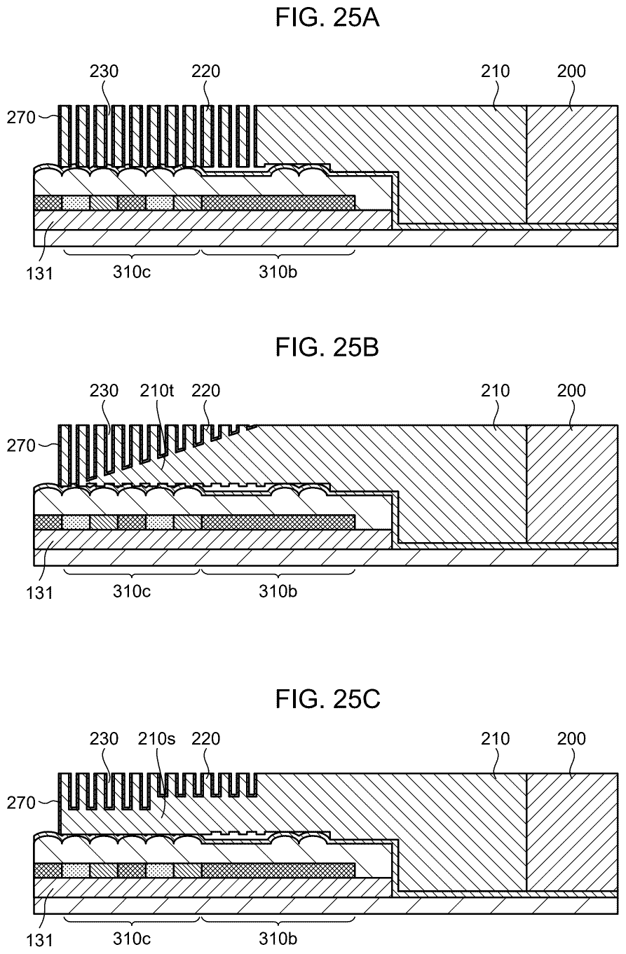

Next, a first example of the manufacturing method for the image pickup device 100 will be described as a fifth embodiment of the present disclosure with reference to FIG. 23. FIG. 23 is a process cross-sectional view illustrating the first example of the manufacturing method for the image pickup device 100 according to the present embodiment.

Here, a description will be given of the manufacturing method for the image pickup device 100 according to the first modification of the first embodiment illustrated in the middle part (B) of FIG. 9.

First, as illustrated in the upper left part of FIG. 23, a resist 700 is applied onto the sealing material 210, and patterning is performed so that the resist 700 remains only on the outer peripheral portion of the image pickup device 100. Next, as illustrated in the left middle part of FIG. 23, hard baking is performed on the resist 700 to make the angle of the pattern end of the resist 700 gentle (taper is formed at the pattern end). Alternatively, gradation exposure is performed using a halftone mask or the like to form a tapered shape at the pattern end of the resist 700.

Next, as illustrated in the lower left part of FIG. 23, a resist 702 is applied over the resist 700. Then, as illustrated in the upper right part of FIG. 23, the resist 702 is patterned in a pillar shape.

As illustrated in the lower right part of FIG. 23, etching conditions (gas type and the like) are adjusted so that etching rates of the resist 700 and the sealing material 210 are equal to each other (selection ratio 1), and the shape of the resist 702 is transferred to the resist 700 and the sealing material 210. Further, the resists 700 and 702 are removed.

Note that, thereafter, bonding to the glass substrate 500 is performed, and the image pickup device 100 can be manufactured by use of the manufacturing method of the third embodiment of the present disclosure described above.

### 6.2 Second Example of Manufacturing Method

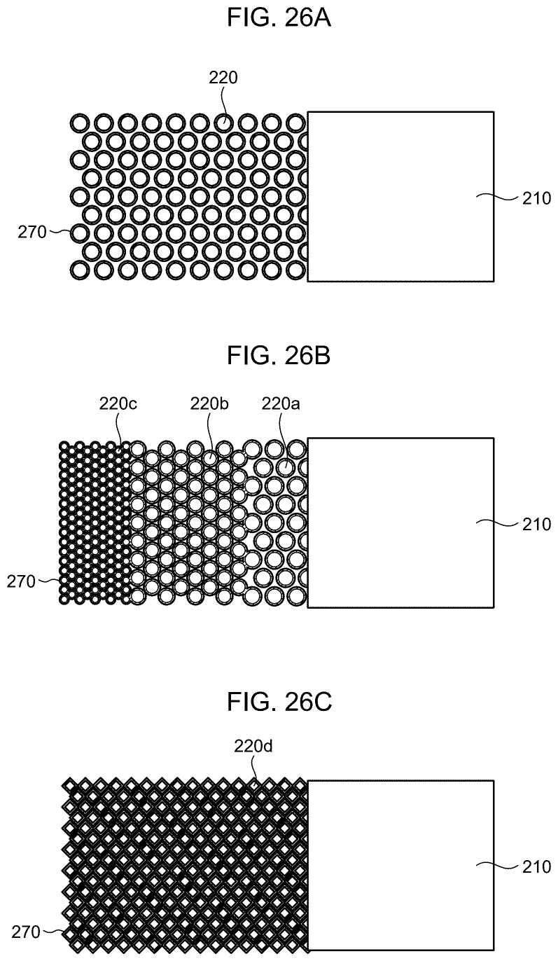

Next, a second example of the manufacturing method for the image pickup device 100 will be described as the fifth embodiment of the present disclosure with reference to FIG. 24. FIG. 24 is a process cross-sectional view illustrating the second example of the manufacturing method for the image pickup device 100 according to the present embodiment. Here, a description will be given of the manufacturing method for the image pickup device 100 according to the first modification of the first embodiment illustrated in the lower part (C) of FIG. 9.

First, as illustrated in the upper left part of FIG. 24, the resist 700 is applied onto the sealing material 210, and patterning is performed so that the resist 700 remains only on the outer peripheral portion of the image pickup device 100. Then, an end portion of the sealing material 210 to be exposed from the resist 700 is etched.

Next, as illustrated in the left middle part of FIG. 24, after the resist 700 is removed, the resist 700 is applied again. Then, a pillar shape is patterned at an end portion of the resist 700. Then, as illustrated in the lower left part of FIG. 24, the sealing material 210 is etched along the pattern of the resist 700.

Next, as illustrated in the upper right part of FIG. 24, after the resist 700 is removed, the resist 700 is applied again. Then, a pillar shape is patterned on a part of the newly applied resist 700. Then, as illustrated in the right middle part of FIG. 24, the sealing material 210 is etched along the pattern of the resist 700.

Then, as illustrated in the lower right part of FIG. 24, the resist 700 is removed. Such a process is repeated according to the number of steps of the staircase structure of the sealing material 210.

Note that, thereafter, bonding to the glass substrate 500 is performed, and the image pickup device 100 can be manufactured by use of the manufacturing method of the third embodiment of the present disclosure described above.

### 6.3 Third Example of Manufacturing Method

Next, a third example of the manufacturing method for the image pickup device 100 will be described as the fifth embodiment of the present disclosure. Here, a description will be given of the manufacturing method for the image pickup device 100 according to the first modification of the first embodiment illustrated in the middle part (B) and the lower part (C) of FIG. 9.

The resist 700 is applied onto the sealing material 210. Then, exposure intensity of each portion is adjusted by use of a gray scale exposure mask to form a pattern of a desired shape on the resist 700. Alternatively, exposure is performed with light intensity corresponding to each position using laser direct drawing, and a pattern having a desired shape is formed on the resist 700.

Then, etching conditions (gas type and the like) are adjusted so that etching rates of the resist 700 and the sealing material 210 are equal to each other (selection ratio 1), and the shape of the resist 700 is transferred to the sealing material 210. Further, the resist 700 is removed.

Note that, thereafter, bonding to the glass substrate 500 is performed, and the image pickup device 100 can be manufactured by use of the manufacturing method of the third embodiment of the present disclosure described above.

### 7. Sixth Embodiment

### 7.1 Detailed Configuration

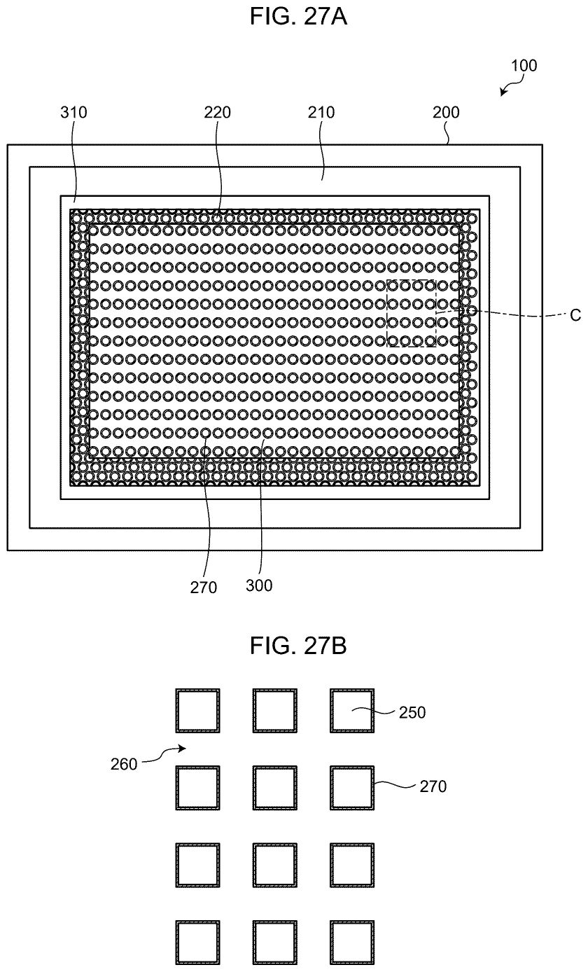

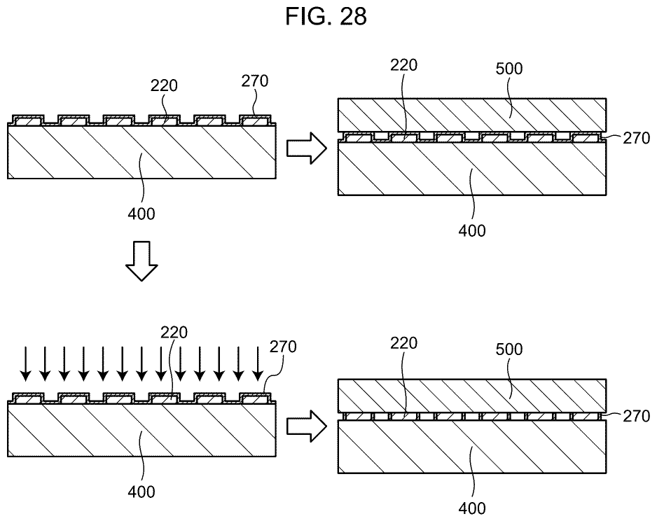

Next, with reference to FIGS. 25 and 26, a description will be given of a detailed configuration of the image pickup device 100 according to a sixth embodiment of the present disclosure. FIG. 25 is a cross-sectional view illustrating a structure example of the image pickup device 100 according to the present embodiment, and FIG. 26 is a plan view illustrating the structure example of the image pickup device 100 according to the present embodiment. In the present embodiment, by covering of the surfaces of the sealing materials 200 and 210 and the pillar 220 with a layer having a refractive index lower than that of the sealing materials 200 and 210 and the pillar 220, the occurrence of the flares is further suppressed.

In the present embodiment, for example, as illustrated in FIG. 25A, the side surface of each pillar 220 is covered with a covering layer (first covering layer) 270 including a material (first low refractive material) having a refractive index lower than that of a material forming the pillar 220. In the present embodiment, for example, in a case where the refractive index of the material forming the pillar 220 is from 1.4 to 1.6, the refractive index of the covering layer 270 is preferably greater than 1 and less than or equal to 1.4. In addition, in the present embodiment, for example, the covering layer 270 can contain magnesium fluoride or porous silicon oxide. Further, in the present embodiment, in view of influence on the sealing material 200 and the like, the covering layer 270 preferably includes a material capable of forming a film at about 200° C. or lower. Furthermore, in the present embodiment, the refractive index of the covering layer 270 may be changed according to a position of the pillar 220 in the image pickup device 100.

As described above, in the present embodiment, by covering of the side surface of the pillar 220 with the covering layer 270 including the material having the refractive index lower than that of the material forming the pillar 220, light is less likely to be reflected by the side surface of the pillar 220. As a result, according to the present embodiment, incident light from the outside is less likely to be reflected by the plurality of pillars 220 and reach the inner end portion of the sealing material 210. Thus, according to the present embodiment, since light is less likely to be uniformly reflected at the inner end portion of the sealing material 210, it is possible to avoid the occurrence of the flare F that occurs at the image end portion and may occur in the cavity structure.

Also in the present embodiment, for example, as illustrated in the middle part (B) and the lower part (C) of FIG. 25, the sealing material 210 may be extended and provided to a part of the optical black region 310b or the non-effective pixel region 310c of the semiconductor substrate 131. The pillars 220 may be provided on a portion where the sealing material 210 is extended. Specifically, as illustrated in the middle part (B) of FIG. 25, the sealing material 210 may include the extended portion 210t extending over a part of the optical black region 310b or the non-effective pixel region 310c. Further, the upper surface of the extended portion 210t may be formed to be a slope in which the upper surface becomes higher at a position closer to the outer side of the image pickup device 100. In addition, the plurality of pillars 220 may be provided on the upper surface of the extended portion 210t.

Furthermore, in the present embodiment, as illustrated in the lower part (C) of FIG. 25, the sealing material 210 may include the extended portion 210s extending on a part of the optical black region 310b and the non-effective pixel region 310c. Further, the upper surface of the extended portion 210s may be formed to have a staircase structure in which the upper surface becomes higher at a position closer to the outer side of the image pickup device 100. In addition, the plurality of pillars 220 may be provided on the upper surface of the extended portion 210s.

Furthermore, in the present embodiment, the side surface of the sealing material (first sealing material) 210 located on the effective pixel region 150 side may be covered with a covering layer (second covering layer) including a material (second low refractive material) having a refractive index lower than that of the material forming the sealing material 210. In the present embodiment, for example, in a case where the refractive index of the material forming the sealing material 210 is from 1.4 to 1.6, the refractive index of the covering layer is preferably greater than 1 and equal to or less than 1.4. In addition, in the present embodiment, for example, the covering layer can contain magnesium fluoride or porous silicon oxide. In the present embodiment, by covering of the side surface of the sealing material 210 with a covering layer including a material having a refractive index lower than that of the material forming the sealing material 210, reflection of light on the side surface of the sealing material 210 can be suppressed. As a result, according to the present embodiment, since light is less likely to be uniformly reflected at the inner end portion of the sealing material 210, it is possible to avoid the occurrence of the flare F that occurs at the image end portion and may occur in the cavity structure.

In the present embodiment, the covering layer may include a stacked layer including a plurality of materials having a refractive index lower than that of the material forming the pillar 220 or the sealing material 210. In this case, it is preferable that the refractive index gradually increases from the outermost layer toward the pillar 220 or the sealing material 210. By doing so, reflection on the surfaces of the pillar 220 and the sealing material 210 can be further suppressed. In addition, in the present embodiment, even in a case where the covering layer is a single layer, the refractive index may gradually increase from the outermost layer toward the pillar 220 or the sealing material 210. By doing so, reflection on the surfaces of the pillar 220 and the sealing material 210 can be further suppressed.

In addition, also in the present embodiment, as illustrated in the middle part (B) of FIG. 26, in the plurality of pillars 220, the cross-sectional area of the pillar 220 may be sequentially reduced as approaching the effective pixel region 300. As described above, in the present embodiment, by changing the cross-sectional area of the pillar 220 according to a relative position with respect to the effective pixel region 300, it is possible for the plurality of pillars 220, particularly, the pillars 220 at positions closer to the effective pixel region 300 to irregularly reflect light effectively. Thus, in the present embodiment, it is possible to further avoid the occurrence of the flare F that occurs at the image end portion.

Further, in the present embodiment, as illustrated in the lower part (C) of FIG. 26, the pillar 220d may have a substantially polygonal cross section (a cross section obtained by cutting of the pillar 220d in parallel to the plane of the semiconductor substrate 131). Further, in a case where the cross section of the pillar 220 has a polygonal shape, it is preferable that the vertex of the corner of the polygonal shape is directed toward the center of the effective pixel region 300. By doing so, the light reflected by the side surface of the pillar 220 is irregularly reflected in a direction other than the direction toward the center of the effective pixel region 300. As a result, according to the present embodiment, it is possible to avoid that the reflected light reaches the effective pixel region 300 again, and avoid the occurrence of the flares.

Also in the present embodiment, the arrangement of the pillars 220 is not limited to being regular, and the pillars 220 may be randomly arranged in a plan view.

Further, in the present embodiment, the cross section when the pillar 220 is cut along the film thickness direction of the semiconductor substrate 131 is not limited to a substantially cylindrical or substantially prismatic column having a rectangular cross section, and, for example, may be a substantially conical or substantially pyramidal shape having a cross section having a vertex upward, or may be a substantially conical or substantially pyramidal shape having a cross section having a vertex downward. Furthermore, for example, the pillar 220 may have a shape in which two substantially conical or substantially pyramidal shapes whose vertexes are cut are stacked, or may have a shape in which two substantially conical or substantially pyramidal shapes are stacked such that the vertexes before being cut face inward. In addition, for example, the pillar 220 may have a substantially conical or substantially pyramidal shape in which the vertex is cut, or may have a shape in which the vertex is cut of a substantially conical or substantially pyramidal shape having the vertex upward. In a case where the shape of the pillar 220 is complicated, the covering layer 270 is formed after the pillar 220 is processed into a desired shape.

### 7.2 Modification

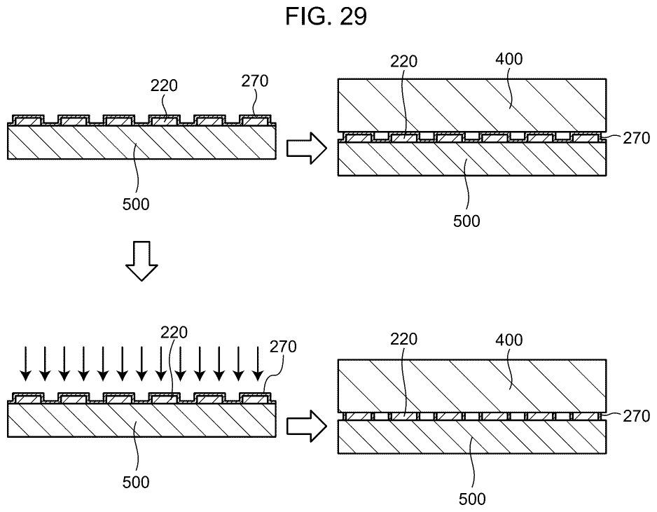

Next, with reference to FIGS. 27A and 27B, a description will be given of a detailed configuration of the image pickup device 100 according to a modification of the present embodiment. FIG. 27A is a plan view illustrating a structure example of the image pickup device 100 according to the modification of the present embodiment, and FIG. 27B is an enlarged view illustrating the structure example of the image pickup device 100 according to the modification of the present embodiment.

Also in the present modification, similarly to the second embodiment described above, the cavity 240 may not be uniformly provided over the entire effective pixel region 300, but the cavity 260 may be provided only on specific photodiodes PD in the effective pixel region 300, and the resin layer 250 may be provided on other photodiode PD in the effective pixel region 300.

Specifically, in the present modification, as illustrated in FIGS. 27A and 27B, there is the cavity (gap) 260 above a specific photodiode PD in the effective pixel region 300 between the effective pixel region 300 and the glass substrate 134 (not illustrated). In addition, the cavity 260 may be a vacuum, or may be filled with a gas such as air, nitrogen, or argon.

Further, in the present modification, the resin layer 250 is provided on the remaining photodiodes PD in the effective pixel region 300 between the effective pixel region 300 and the glass substrate 500 (not illustrated).

The resin layer 250 preferably includes a material having the same refractive index as that of the pillar 220 or a material having a refractive index lower than that of the pillar 220, for example, a resin having a refractive index of from 1.3 to 1.4. Further, in the present modification, the side surface of the resin layer 250 is covered with the covering layer 270 including a material having a refractive index lower than that of the material forming the resin layer 250.

In addition, the on-chip lens 132 for the photodiode PD located below the resin layer 250 preferably includes a material having a refractive index higher than that of the resin layer 250. For example, in a case where the resin layer 250 has a refractive index lower than that of the pillar 220, specifically, in the case of a resin having a refractive index of from 1.3 to 1.4, the on-chip lens 132 preferably includes a material having a refractive index of from 1.4 to 1.6. In addition, for example, in a case where the resin layer 250 is a resin having a refractive index of from 1.3 to 1.4 and in a case where the resin layer 250 is a material having the same refractive index as that of the pillar 220, the on-chip lens 132 can include silicon nitride or the like. Further, as the resin layer 250 itself, a wavelength conversion film that converts X-rays into visible light or converts infrared light into visible light may be introduced, and by doing so, it is possible to expand the wavelength range of the light that can be detected by the image pickup device 100.

As described above, in the present modification, by providing the resin layer 250 also on a part of the effective pixel region 300, it is possible to further strengthen the bonding between the glass substrate 500 and the semiconductor substrate 131. As a result, in the present modification, the image pickup device 100 can be easily downsized to a chip size level.

Note that, in the present embodiment and the modification, the image pickup device 100 is not limited to the structure illustrated in FIGS. 25 to 27B.

### 7.3 Manufacturing Method

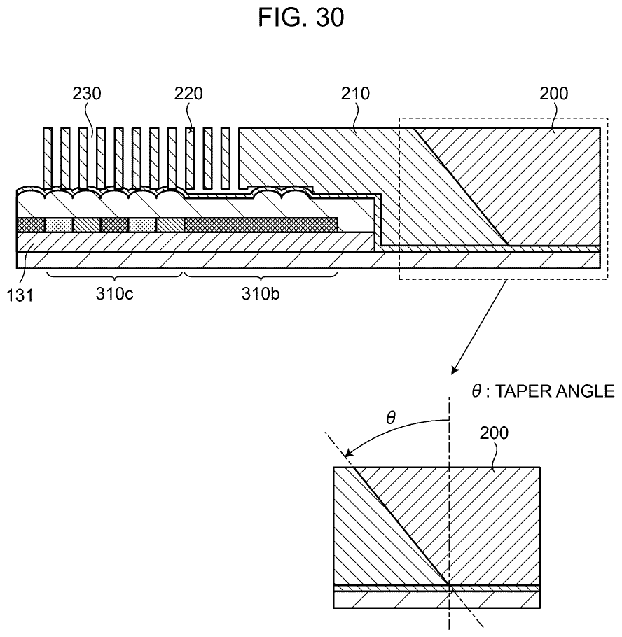

Next, an example of the manufacturing method for the image pickup device 100 according to the present embodiment will be described with reference to FIG. 28. FIG. 28 is a process cross-sectional view illustrating the example of the manufacturing method for the image pickup device 100 according to the present embodiment.

First, as illustrated in the upper left part of FIG. 28, patterning is performed on the sealing material provided on the semiconductor substrate 400 using a method such as lithography. Further, the covering layer 270 is formed on the surface of the pillar 220 formed by the patterning. At this time, in a case where the aspect ratio of the pillars 220 (the ratio of the height of the pillars 220/the distance between the pillars 220) is large, or in a case where the shape of the pillars 220 is complicated, it is preferable to form the covering layer 270 by using an atomic layer deposition (ALD) method. However, the present embodiment is not limited to the ALD method, and other film forming methods may be used such as a chemical vapor deposition (CVD) method, a physical vapor deposition (PVD) method, and coating. Further, in a case where the covering layer 270 is formed on a hydrophobic surface, it is preferable to perform surface modification by plasma treatment or the like.

Next, as illustrated in the upper right part of FIG. 28, the glass substrate 500 is bonded onto the semiconductor substrate 400 provided with the pillars 220. Alternatively, as illustrated in the lower left part of FIG. 28, the covering layer 270 formed on the upper surface of the pillars 220 and the upper surface of the semiconductor substrate 400 may be removed by vertical etching, and then bonded to the glass substrate 500 as illustrated in the lower right part of FIG. 28.

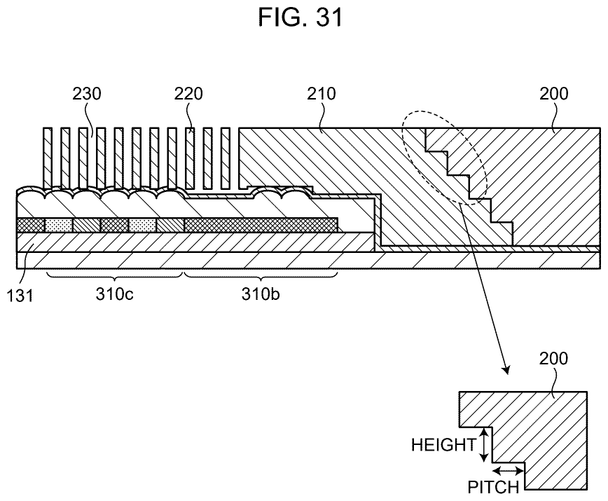

Next, a second example of the manufacturing method for the image pickup device 100 according to the present embodiment will be described with reference to FIG. 29. FIG. 29 is a process cross-sectional view illustrating the second example of the manufacturing method for the image pickup device 100 according to the present embodiment.

First, as illustrated in the upper left part of FIG. 29, patterning is performed on the sealing material provided on the glass substrate 500 using a method such as lithography. Further, the covering layer 270 is formed on the surface of the pillar 220 formed by the patterning.

Next, as illustrated in the upper right part of FIG. 29, the semiconductor substrate 400 is bonded onto the glass substrate 500 provided with the pillars 220.

Alternatively, as illustrated in the lower left part of FIG. 29, the covering layer 270 formed on the upper surface of the pillars 220 and the upper surface of the glass substrate 500 may be removed by vertical etching, and then bonded to the semiconductor substrate 400 as illustrated in the lower right part of FIG. 29.

As described above, the present embodiment can be implemented without significant change of the manufacturing process of the image pickup device 100.

### 8. Seventh Embodiment

### 8.1 Detailed Configuration

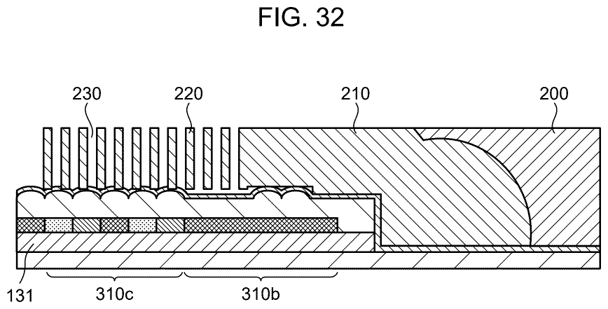

Next, with reference to FIGS. 30 to 32, a description will be given of a detailed configuration of the image pickup device 100 according to a seventh embodiment of the present disclosure. FIGS. 30 to 32 are cross-sectional views each illustrating a structure example of the image pickup device 100 according to the present embodiment. In the present embodiment, the shape of the sealing material 200 is devised to further suppress the occurrence of the flares.

As illustrated in the upper part of FIG. 30, in the image pickup device 100 according to the present embodiment, a side surface on the effective pixel region 150 side of the sealing material 200 provided along the inner side of the outer periphery of the image pickup device 100 may have a reverse tapered structure.

Specifically, in a cross-sectional view of the sealing material 200 (a cross section when the image pickup device 100 is cut along the film thickness direction of the semiconductor substrate 131), the side surface of the sealing material 200 has a structure expanding upward in the drawing.

In addition, in the present embodiment, as illustrated in the lower part of FIG. 30, a taper angle θ of the sealing material 200 can be from 1° to 89°, and preferably from 10° to 70°.

As described above, in the present embodiment, by making the side surface of the sealing material 200 such a reverse tapered structure, it is possible to suppress that external light reflected by the side surface of the sealing material 200 travels to the effective pixel region 150. As a result, according to the present embodiment, since light is less likely to be uniformly reflected by the side surface of the sealing material 200, it is possible to avoid the occurrence of the flare F that occurs at the image end portion and may occur in the cavity structure.

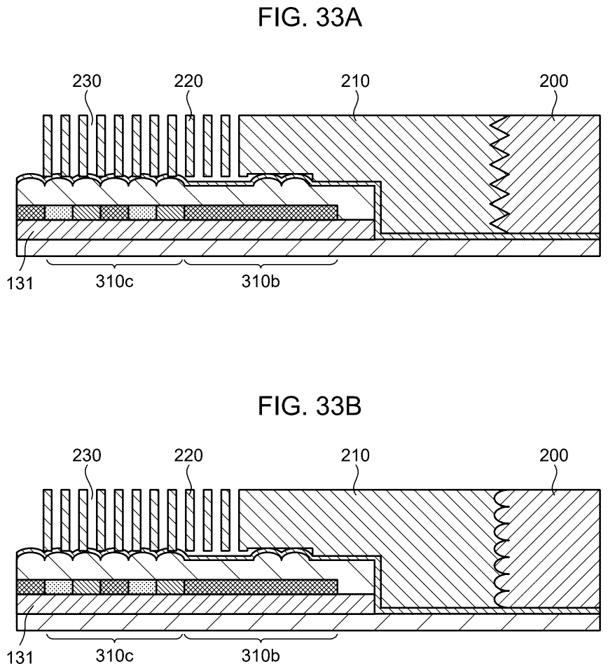

In addition, as illustrated in the upper part of FIG. 31, in the image pickup device 100 according to the present embodiment, the side surface on the effective pixel region 150 side of the sealing material 200 provided along the inner side of the outer periphery of the image pickup device 100 may have a reverse staircase structure. Specifically, in a cross-sectional view of the sealing material 200 (a cross section when the image pickup device 100 is cut along the film thickness direction of the semiconductor substrate 131), the side surface of the sealing material 200 has a structure expanding upward and being step-shaped.

In the present embodiment, as illustrated in the lower part of FIG. 31, the height and pitch of the staircase structure on the side surface of the sealing material 200 can be from 1 nm to 1 mm. Further, in the present embodiment, the number of steps of the staircase is not particularly limited, and is not limited to being periodic. That is, in the present embodiment, the height and pitch of the staircase structure on the side surface of the sealing material 200 may be random.

As described above, in the present embodiment, by making the side surface of the sealing material 200 such a staircase structure that expands upward in the drawing, it is possible to suppress that external light reflected by the side surface of the sealing material 200 travels to the effective pixel region 150. As a result, according to the present embodiment, since light is less likely to be uniformly reflected by the side surface of the sealing material 200, it is possible to avoid the occurrence of the flare F that occurs at the image end portion and may occur in the cavity structure.

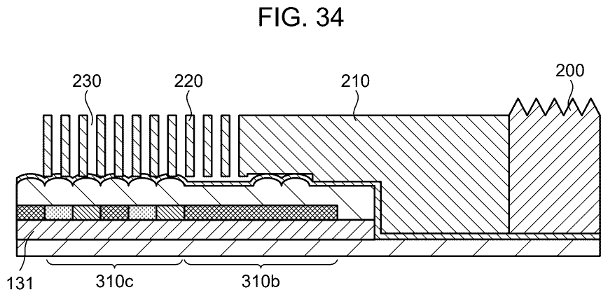

In addition, as illustrated in FIG. 32, in the image pickup device 100 according to the present embodiment, the side surface on the effective pixel region 150 side of the sealing material 200 provided along the inner side of the outer periphery of the image pickup device 100 may have an eaves structure. Specifically, in a cross-sectional view of the sealing material 200 (a cross section when the image pickup device 100 is cut along the film thickness direction of the semiconductor substrate 131), the side surface of the sealing material 200 expands upward in the drawing and has an arc-shaped smooth concave surface toward the inner side of the sealing material 200.

As described above, in the present embodiment, by making the side surface of the sealing material 200 such an eaves structure, it is possible to suppress that external light reflected by the side surface of the sealing material 200 travels to the effective pixel region 150. As a result, according to the present embodiment, since light is less likely to be uniformly reflected by the side surface of the sealing material 200, it is possible to avoid the occurrence of the flare F that occurs at the image end portion and may occur in the cavity structure.

In the present embodiment, the eaves structure of the side surface of the sealing material 200 is not limited to a smooth surface, and may be a wavy rough surface, a rough surface having unevenness, a step-shaped surface, or the like. By doing so, since light is less likely to be uniformly reflected at the inner end portion of the sealing material 200, it is possible to avoid the occurrence of the flare F that occurs at the image end portion and may occur in the cavity structure.

### 8.2 First Modification

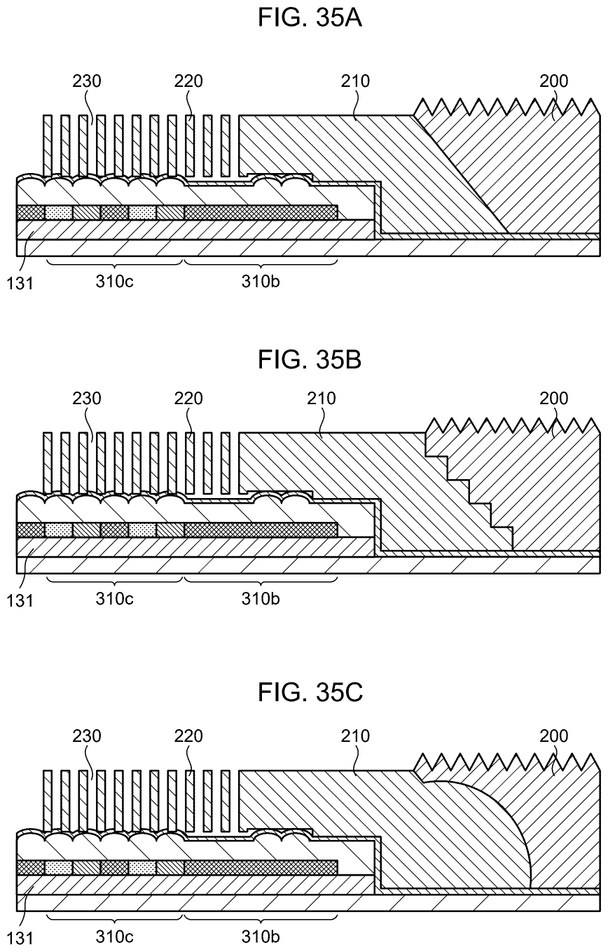

Next, with reference to FIG. 33, a description will be given of a detailed configuration of the image pickup device 100 according to a first modification of the present embodiment. FIG. 33 is a cross-sectional view illustrating a structure example of the image pickup device 100 according to the first modification of the present embodiment.

As illustrated in the upper part (A) of FIG. 33, in the image pickup device 100 according to the present first modification, the side surface on the effective pixel region 150 side of the sealing material 200 provided along the inner side of the outer periphery of the image pickup device 100 may be a substantially triangular wave-shaped surface (including a moth-eye structure). Alternatively, as illustrated in the lower part (B) of FIG. 33, in the image pickup device 100 according to the present first modification, the side surface on the effective pixel region 150 side of the sealing material 200 provided along the inner side of the outer periphery of the image pickup device 100 may be a substantially sinusoidal surface. Alternatively, in the present first modification, the side surface of the sealing material 200 may be an uneven-shaped surface, or may be a randomly roughened surface.

As described above, in the present first modification, by making the side surface of the sealing material 200 such a rough surface, it is possible for light to be irregularly reflected easily by the side surface of the sealing material 200, and it is possible to suppress that external light reflected by the side surface of the sealing material 200 travels to the effective pixel region 150. As a result, according to the present embodiment, since light is less likely to be uniformly reflected by the side surface of the sealing material 200, it is possible to avoid the occurrence of the flare F that occurs at the image end portion and may occur in the cavity structure.

### 8.3 Second Modification

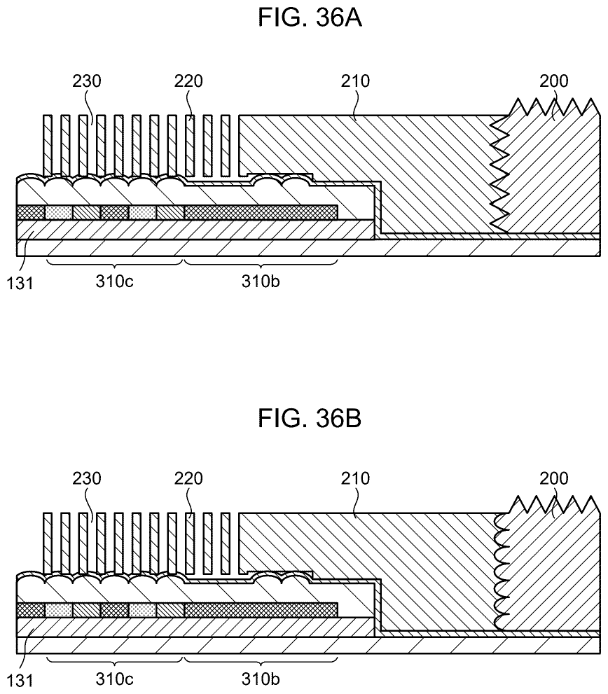

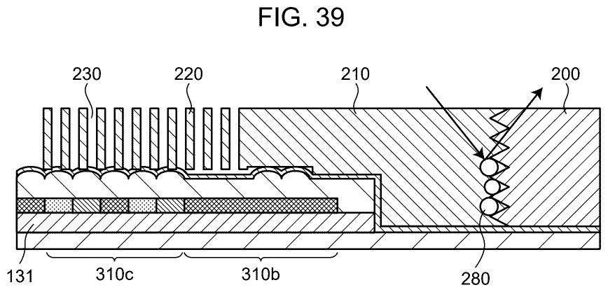

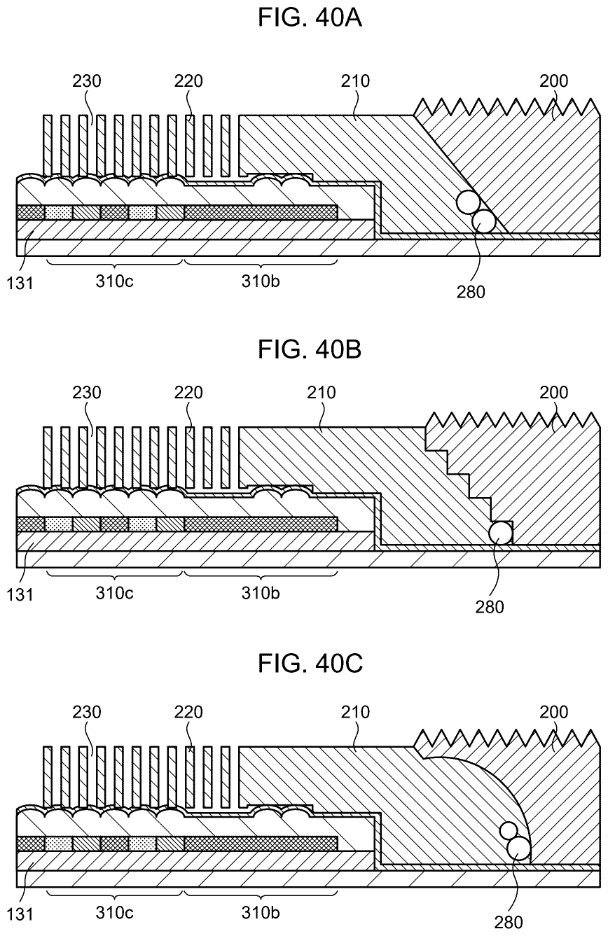

Next, with reference to FIGS. 34 to 38, a description will be given of a detailed configuration of the image pickup device 100 according to a second modification of the present embodiment. FIGS. 34 to 36 are cross-sectional views each illustrating a structure example of the image pickup device 100 according to the second modification of the present embodiment. FIG. 37 is an explanatory diagram for explaining the first and second modifications of the present embodiment, and FIG. 38 is a plan view illustrating a structure example of the image pickup device 100 according to the first and second modifications of the present embodiment.

As illustrated in FIG. 34, in the image pickup device 100 according to the second modification, the upper surface of the sealing material 200 provided along the inner side of the outer periphery of the image pickup device 100 may be a substantially triangular wave-shaped surface (including a moth-eye structure).

As described above, in the present second modification, by making the upper surface of the sealing material 200 such a rough surface, it is possible for light to be irregularly reflected easily by the upper surface of the sealing material 200, and it is possible to suppress that external light reflected by the upper surface of the sealing material 200 travels to the glass substrate 500 above (not illustrated). As a result, according to the present second modification, light is not reflected at the boundary of the glass substrate 500, and reflected light in the image pickup device 100 does not reach the light receiving surface of the semiconductor substrate 131 again. Thus, in the second modification, similarly to the cavity structure described above, it is possible to avoid the occurrence of the plurality of flares R that constitutes the ring surrounding the image S of the incident light and may occur in the cavity-less structure described above.

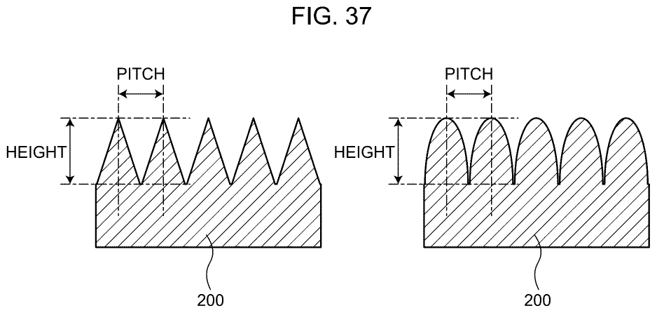

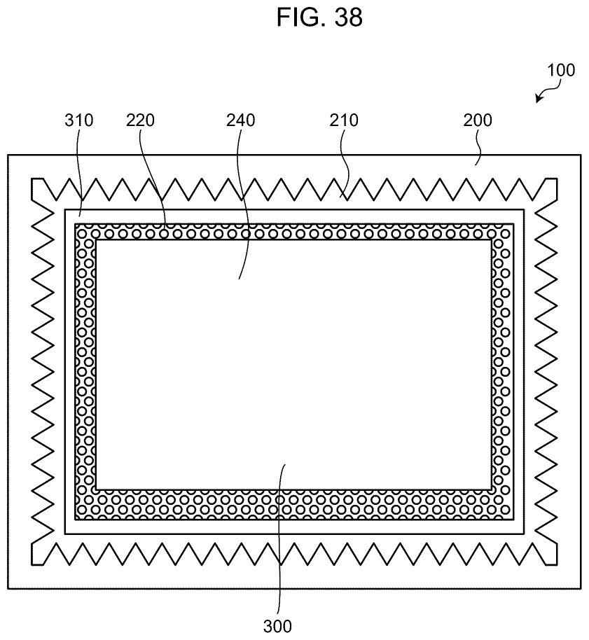

Note that the present second modification can be applied to the present embodiment, and in this case, the structure of FIG. 35 can be obtained. In addition, the present second modification can be applied to the above-described first modification, and in this case, the structure of FIG. 36 can be obtained.

In the first and second modifications, the structures of the side surface and the upper surface of the sealing material 200 may be an uneven-shaped surface, a randomly roughened surface, a substantially triangular wave-shaped surface (including a moth-eye structure), or a substantially sinusoidal surface. Note that, in the present first and second modifications, the height and pitch of the protrusions on the side surface and the upper surface of the sealing material 200 are not particularly limited. In the present first and second modifications, as illustrated in FIG. 37, the height and pitch of these protrusions are preferably from about 1 nm to 1 mm, for example. The height and pitch of the protrusions on the side surface and the upper surface of the sealing material 200 are not limited to being periodic, and may be random.

Note that it is possible to obtain such structures of the side surface and the upper surface of the sealing material 200, for example, by roughening the side surface and the upper surface of the sealing material 200 by blast treatment. Details of the manufacturing method for the image pickup device 100 according to the first and second modifications will be described later.

In addition, in a plan view in a case where the side surface of the sealing material 200 is made to have an uneven shape (in a case where the image pickup device 100 is viewed from above), for example, the image pickup device 100 can have a form as illustrated in FIG. 38.

### 8.4 Third Modification

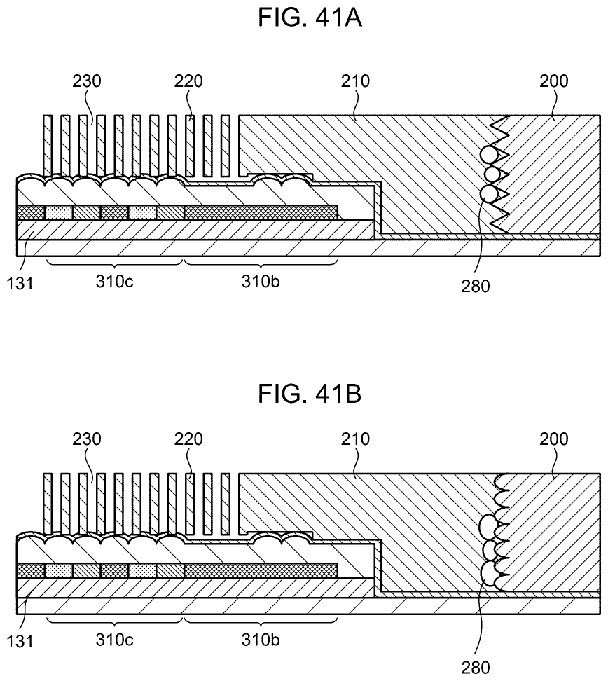

Next, with reference to FIGS. 39 to 41, a description will be given of a detailed configuration of the image pickup device 100 according to a third modification of the present embodiment. FIGS. 39 to 41 are cross-sectional views each illustrating a structure example of the image pickup device 100 according to the third modification of the present embodiment.

As illustrated in FIG. 39, in the image pickup device 100 according to the present third modification, there may be gaps 280 between the sealing material 200 and the sealing material 210. In the present third modification, the gaps 280 may be uniformly arranged, randomly arranged, or partially arranged between the sealing material 200 and the sealing material 210. In addition, in the present third modification, the inside of the gaps 280 is not limited to being a cavity, and may be filled with air, a gas having a low refractive index, or the like.

As described above, in the present third modification, by provision of the gaps 280 between the sealing material 200 and the sealing material 210, light is irregularly reflected easily near the side surface of the sealing material 200. As a result, in the present third modification, since light is less likely to be uniformly reflected by the side surface of the sealing material 200, it is possible to avoid the occurrence of the flare F that occurs at the image end portion and may occur in the cavity structure. In addition, in the present third modification, light is irregularly reflected easily near the side surface of the sealing material 200, so that it is possible to suppress that external light reflected by the side surface of the sealing material 200 travels to the glass substrate 500 above (not illustrated). As a result, according to the present fourth modification, light is not reflected at the boundary of the glass substrate 500, and reflected light in the image pickup device 100 does not reach the light receiving surface of the semiconductor substrate 131 again. Thus, according to the present fourth modification, similarly to the cavity structure described above, it is also possible to avoid the occurrence of the plurality of flares R that constitutes the ring surrounding the image S of the incident light and may occur in the cavity-less structure described above.

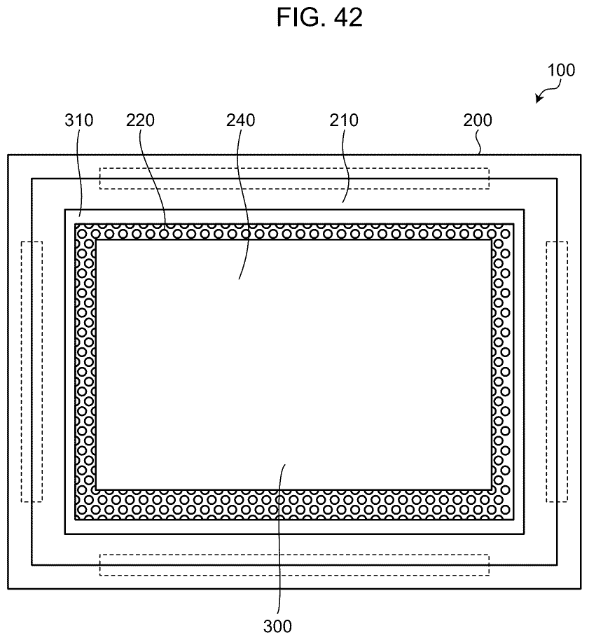

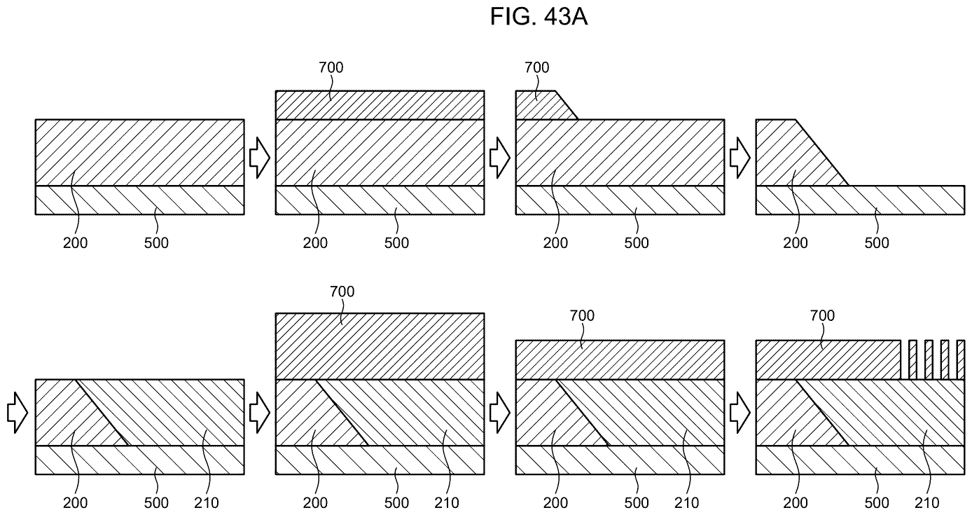

The present third modification is not limited to a case where the side surface of the sealing material 200 has an uneven shape. For example, the present third modification can be applied to the present embodiment, and in this case, the structure of FIG. 40 can be obtained. In addition, the present third modification can be applied to the above-described first modification, and in this case, the structure of FIG. 41 can be obtained.

### 8.5 Fourth Modification

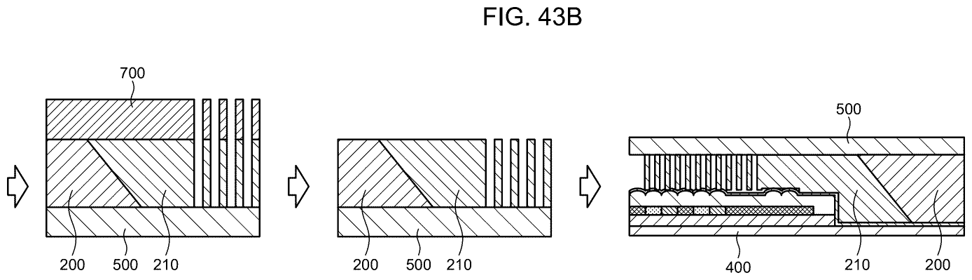

Next, with reference to FIG. 42, a description will be given of a detailed configuration of the image pickup device 100 according to a fourth modification of the present embodiment. FIG. 42 is a plan view illustrating a structure example of the image pickup device 100 according to the fourth modification of the present embodiment.

The structures of the side surface and the upper surface of the sealing material 200 according to the present embodiment and the modifications are not limited to being provided along the entire side surface of the sealing material 200 on the effective pixel region 150 side. For example, a rough surface structure of the side surface and the upper surface of the sealing material 200 according to the present embodiment and the modifications may be provided along a part of the side surface surrounded by a broken line as illustrated in FIG. 42. In addition, the side surface and the upper surface of the sealing material 200 may have different structures for respective parts of the side surface surrounded by broken lines as illustrated in FIG. 42.

For example, four corner portions of the image pickup device 100 are far from the effective pixel region 150, and external light hardly enters the four corner portions. Thus, an uneven structure or the staircase structure may not be provided on the side surface of the sealing material 200 at the four corner portions of the image pickup device 100. Alternatively, for example, in a case where external light easily enters the four corner portions of the image pickup device 100, the uneven structure or the staircase structure may be provided only on the side surface of the sealing material 200 at the four corner portions of the image pickup device 100.

Note that, in the present embodiment and the modifications, the image pickup device 100 is not limited to the structure illustrated in FIGS. 30 to 42.

### 8.6 First Example of Manufacturing Method

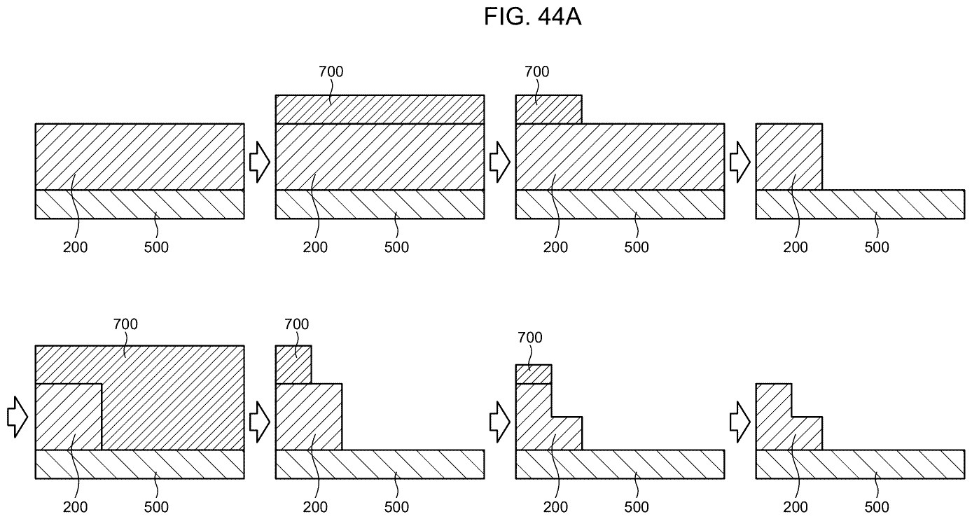

Next, a first example of the manufacturing method for the image pickup device 100 according to the present embodiment will be described with reference to FIGS. 43A and 43B. FIGS. 43A and 43B are process cross-sectional views illustrating the first example of the manufacturing method for the image pickup device 100 according to the present embodiment. Here, a description will be given of an example of the manufacturing method for the image pickup device 100 according to the present embodiment illustrated in FIG. 30.

First, as illustrated on the left side of the upper part of FIG. 43A, the sealing material 200 is formed on the glass substrate 500. Next, as illustrated in the second from the left side of the upper part of FIG. 43A, the resist 700 is applied onto the sealing material 200. Next, as illustrated in the third from the left side of the upper part of FIG. 43A, hard baking is performed to make the angle of the pattern end of the resist 700 gentle (taper the pattern end of the resist 700). Alternatively, gradation exposure is performed using a halftone mask or the like to form a tapered shape at the pattern end of the resist 700.

Next, as illustrated on the right side of the upper part of FIG. 43A, after the sealing material 200 is etched according to the pattern of the resist 700, the resist 700 is removed. Then, as illustrated on the left side of the lower part of FIG. 43A, the sealing material 210 is applied onto the glass substrate 500, and the sealing material 210 is etched as necessary. Next, as illustrated in the second from the left side of the lower part of FIG. 43A, the resist 700 is applied onto the sealing materials 200 and 210. Next, as illustrated in the third from the left side of the lower part of FIG. 43A, the upper surface of the resist 700 is etched, and patterning is performed on the resist 700 as illustrated on the right side of the lower part of FIG. 43A.

Next, as illustrated on the left side of FIG. 43B, the sealing material 210 is etched according to the pattern of the resist 700, and the resist 700 is removed as illustrated in the center of FIG. 43B. Then, as illustrated on the right side of FIG. 43B, the semiconductor substrate 400 is bonded onto the glass substrate 500.

### 8.7 Second Example of Manufacturing Method

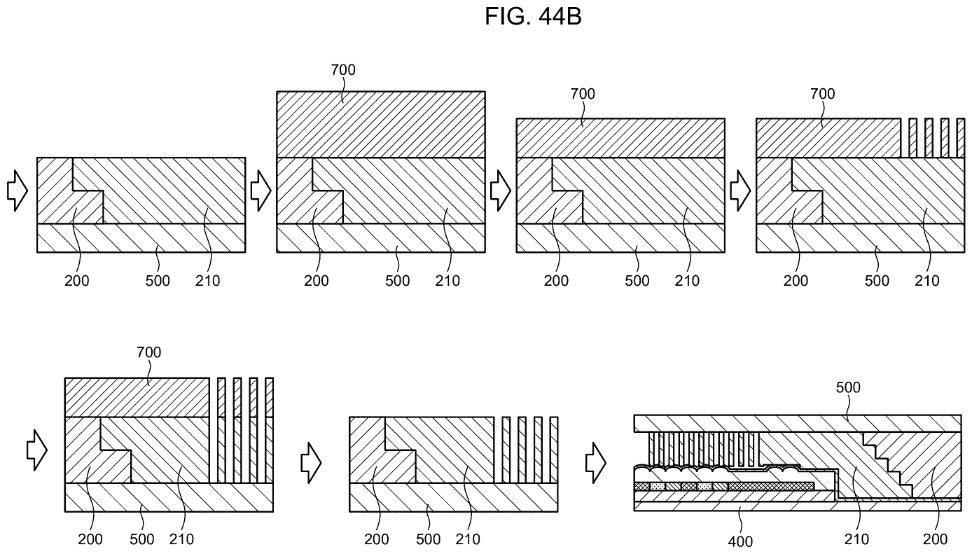

Next, a second example of the manufacturing method for the image pickup device 100 according to the present embodiment will be described with reference to FIGS. 44A and 44B. FIGS. 44A and 44B are process cross-sectional views illustrating the second example of the manufacturing method for the image pickup device 100 according to the present embodiment. Here, a description will be given of an example of the manufacturing method for the image pickup device 100 according to the present embodiment illustrated in FIG. 31.

First, as illustrated on the left side of the upper part of FIG. 44A, the sealing material 200 is formed on the glass substrate 500. Next, as illustrated in the second from the left side of the upper part of FIG. 44A, the resist 700 is applied onto the sealing material 200. Next, as illustrated in the third from the left side of the upper part of FIG. 44A, the resist 700 is patterned. Next, as illustrated on the right side of the upper part of FIG. 44A, after the sealing material 200 is etched according to the pattern of the resist 700, the resist 700 is removed. Then, as illustrated on the left side of the lower part of FIG. 43A, the resist 700 is applied onto the glass substrate 500. Next, as illustrated in the second from the left side of the lower part of FIG. 43A, patterning is performed on the resist 700.

Next, as illustrated in the third from the left side of FIG. 44A, the sealing material 210 is etched according to the pattern of the resist 700, and the resist 700 is removed as illustrated on the right side of the lower part of FIG. 44A. In this way, the staircase structure is formed on the side surface of the sealing material 200.

Then, as illustrated on the left side of the upper part of FIG. 44B, the sealing material 210 is applied onto the glass substrate 500, and the sealing material 210 is etched as necessary. Next, as illustrated in the second from the left side of the upper part of FIG. 44B, the resist 700 is applied onto the sealing materials 200 and 210. Next, as illustrated in the third from the left side of the upper part of FIG. 44B, the upper surface of the resist 700 is etched, and patterning is performed on the resist 700 as illustrated in the upper part side of FIG. 44B.

Next, as illustrated on the left side of the lower part of FIG. 44B, the sealing material 210 is etched according to the pattern of the resist 700, and the resist 700 is removed as illustrated in the center of the lower part of FIG. 44B. Then, as illustrated on the right side of the lower part FIG. 44B, the semiconductor substrate 400 is bonded onto the glass substrate 500.

### 8.8 Third Example of Manufacturing Method

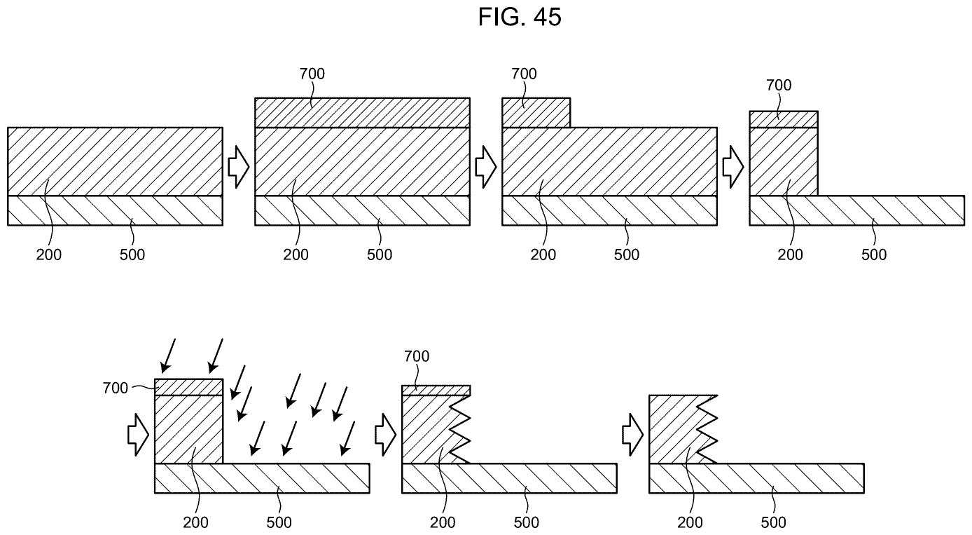

Next, a third example of the manufacturing method for the image pickup device 100 according to the present embodiment will be described with reference to FIG. 45. FIG. 45 is a process cross-sectional view illustrating the third example of the manufacturing method for the image pickup device 100 according to the present embodiment. Here, a description will be given of an example of the manufacturing method for the image pickup device 100 according to the first modification of the present embodiment illustrated in the upper part (A) of FIG. 33.

First, as illustrated on the left side of the upper part of FIG. 45, the sealing material 200 is formed on the glass substrate 500. Next, as illustrated in the second from the left side of the upper part of FIG. 45, the resist 700 is applied onto the sealing material 200. Next, as illustrated in the third from the left side of the upper part of FIG. 45, the resist 700 is patterned. Next, as illustrated on the right side of the upper part of FIG. 45, the sealing material 200 is etched according to the pattern of the resist 700.

Next, as illustrated on the left side of the lower part of FIG. 45, ashing is performed on the side surface of the sealing material 200 to perform blasting. Alternatively, Bosch etching is performed on the side surface of the sealing material 200 (vertical and horizontal plasma etching). In this way, it is possible to obtain a form illustrated in the center of the lower part of FIG. 45. Further, as illustrated on the right side of the lower part FIG. 45, the resist 700 is removed.

Thereafter, bonding to the semiconductor substrate 131 is performed, and the image pickup device 100 can be manufactured by use of the manufacturing method of the third embodiment of the present disclosure described above.

Note that the present manufacturing method is not limited to first forming the sealing material 200 on the glass substrate 500, and the sealing material 200 may be first formed on the semiconductor substrate 400.

### 8.9 Fourth Example of Manufacturing Method

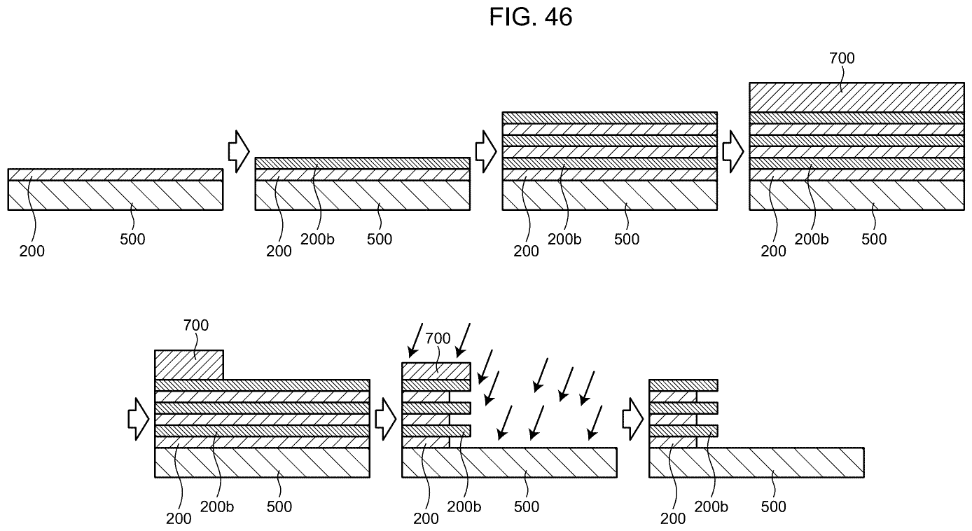

Next, a fourth example of the manufacturing method for the image pickup device 100 according to the present embodiment will be described with reference to FIG. 46.

FIG. 46 is a process cross-sectional view illustrating the fourth example of the manufacturing method for the image pickup device 100 according to the present embodiment. Here, a description will be given of the manufacturing method for the image pickup device 100 including the sealing material 200 having the side surface of the uneven structure.

First, as illustrated on the left side of the upper part of FIG. 46, the sealing material 200 is applied onto the glass substrate 500. Next, as illustrated in the second from the left side of the upper part of FIG. 45, a sealing material 200b including a material different from the sealing material 200 is applied onto the sealing material 200. Specifically, the sealing material 200b is not particularly limited as long as it is a material that is harder to etch than the sealing material 200, and for example, can be a material in which a material such as carbon is included in the sealing material 200.

Next, as illustrated in the third from the left side of the upper part of FIG. 46, the sealing materials 200 and 200b are sequentially applied to form a stacked structure. The film thicknesses of the sealing materials 200 and 200b are not limited to the same, and may be different film thicknesses. Next, as illustrated on the right side of the upper part of FIG. 46, the resist 700 is applied.

Next, as illustrated on the left side of the lower part of FIG. 46, the resist 700 is patterned. Next, as illustrated in the center of the lower part of FIG. 45, etching is performed on the side surfaces of the sealing materials 200 and 200b to remove the resist 700, whereby a form as illustrated on the right side of the lower part of FIG. 46 can be obtained.

Thereafter, bonding to the semiconductor substrate 131 is performed, and the image pickup device 100 can be manufactured by use of the manufacturing method of the third embodiment of the present disclosure described above.

Note that the present manufacturing method is not limited to first forming the sealing material 200 on the glass substrate 500, and the sealing material 200 may be first formed on the semiconductor substrate 400.

### 8.10 Fifth Example of Manufacturing Method

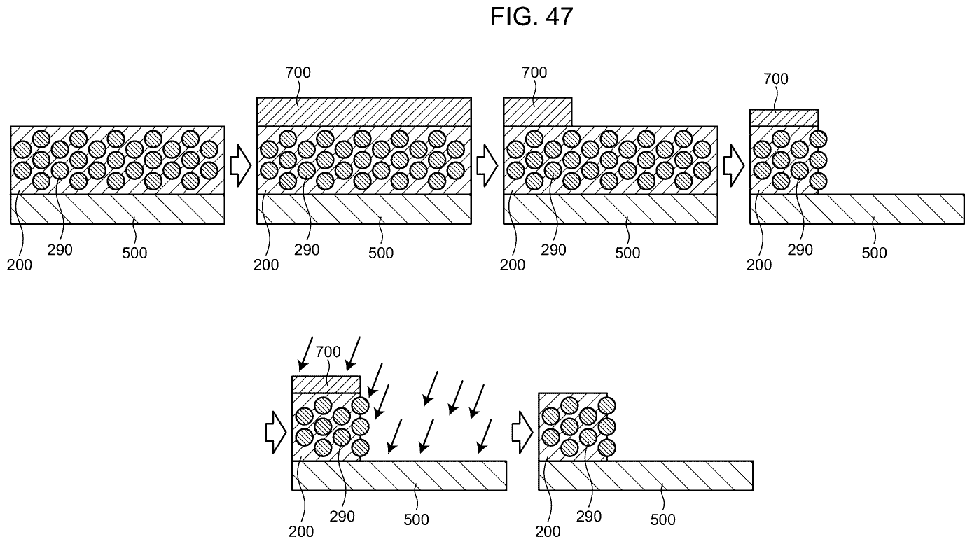

Next, a fifth example of the manufacturing method for the image pickup device 100 according to the present embodiment will be described with reference to FIG. 47.

FIG. 47 is a process cross-sectional view illustrating the fifth example of the manufacturing method for the image pickup device 100 according to the present embodiment. Here, a description will be given of the manufacturing method for the image pickup device 100 including the sealing material 200 having the substantially sinusoidal side surface as illustrated in the lower part (B) of FIG. 33.

First, as illustrated on the left side of the upper part of FIG. 47, the sealing material 200 containing a bead 290 is applied onto the glass substrate 500. The bead 290 is not particularly limited as long as it includes a material that is harder to etch than the sealing material 200, and is not limited to having a spherical shape, and may be, for example, a needle shape or the like.

Next, as illustrated in the second from the left side of the upper part of FIG. 47, the resist 700 is applied. Further, as illustrated in the third from the left side of the upper part of FIG. 47, the resist 700 is patterned. Next, as illustrated on the right side of the upper part of FIG. 47, etching is performed on the sealing material 200. Then, as illustrated on the left side of the lower part of FIG. 47, ashing is performed on the side surface of the sealing material 200 to perform blasting as necessary. Alternatively, Bosch etching is performed on the side surface of the sealing material 200 (vertical and horizontal plasma etching). In this way, it is possible to obtain a form as illustrated on the right side of the lower part FIG. 46.

Thereafter, bonding to the semiconductor substrate 131 is performed, and the image pickup device 100 can be manufactured by use of the manufacturing method of the third embodiment of the present disclosure described above.

Note that the present manufacturing method is not limited to first forming the sealing material 200 on the glass substrate 500, and the sealing material 200 may be first formed on the semiconductor substrate 400.

In addition, the sealing material 200b in the fourth example of the manufacturing method may contain the bead 290 of the present modification.

As described above, the present embodiment and the modifications can be implemented without significant change of the manufacturing process of the image pickup device 100.

### 9. Conclusion

As described above, in each embodiment of the present disclosure, since light is reflected at the boundary between the cavity 240 and the glass substrate 134 due to the presence of the cavity 240 on the effective pixel region 300, reflected light in the image pickup device 100 does not reach the light receiving surface of the semiconductor substrate 131 again. Thus, in the present embodiment, similarly to the cavity structure described above, it is possible to avoid the occurrence of the plurality of flares R that constitutes the ring surrounding the image S of the incident light and may occur in the cavity-less structure described above. Further, in each embodiment of the present disclosure, even in a case where the incident light from the outside travels to the inner end portion of the sealing material 210, the incident light is irregularly reflected complicatedly due to the presence of the plurality of pillars 220 before reaching the inner end portion of the sealing material 210. Thus, in the present embodiment, since light is less likely to be uniformly reflected at the inner end portion of the sealing material 210, it is possible to avoid the occurrence of the flare F that occurs at the image end portion and may occur in the cavity structure. In addition, in each embodiment of the present disclosure, by providing the plurality of pillars 220, it is possible to suppress separation between the glass substrate 134 and the semiconductor substrate 131, so that the area covered by the sealing material 210 can be reduced. Thus, according to the present embodiment, similarly to the cavity-less structure, the image pickup device 100 can be easily downsized to a chip size level.

That is, according to each embodiment of the present disclosure, since both are obtained of the advantages of the cavity-less structure and the advantages of the cavity structure described above, it is possible to easily perform downsizing to the chip size level while suppressing the occurrence of various flares.

In addition, the semiconductor substrates 131 and 136 of the image pickup device 100 according to the embodiments of the present disclosure can be manufactured by use of a method, an apparatus, and conditions used for manufacturing a general semiconductor device. That is, the semiconductor substrates 131 and 136 of the image pickup device 100 according to the present embodiments can be manufactured by use of an existing semiconductor device manufacturing process.

Note that examples of the above-described method include a physical vapor deposition (PVD) method, a chemical vapor deposition (CVD) method, and an ALD method. Examples of the PVD method include a vacuum vapor deposition method, an electron beam (EB) vapor deposition method, various sputtering methods (magnetron sputtering method, radio frequency (RF)-direct current (DC) coupled bias sputtering method, electron cyclotron resonance (ECR) sputtering method, counter target sputtering method, high frequency sputtering method, and the like), an ion plating method, a laser ablation method, a molecular beam epitaxy (MBE) method, and a laser transfer method. In addition, examples of the CVD method include a plasma CVD method, a thermal CVD method, an organic metal (MO) CVD method, and a photo CVD method. Further, other methods include: an electrolytic plating method, an electroless plating method, and a spin coating method; an immersion method; a cast method; a micro-contact printing method; a drop cast method; various printing methods such as a screen printing method, an inkjet printing method, an offset printing method, a gravure printing method, and a flexographic printing method; a stamping method; a spray method; and various coating methods such as an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, and a calendar coater method. Further, examples of the patterning method include chemical etching such as shadow mask, laser transfer, and photolithography, and physical etching using ultraviolet rays, laser, or the like. In addition, examples of the planarization technique include a chemical mechanical polishing (CMP) method, a laser planarization method, a reflow method, and the like.

### 10. Application Example

### 10.1 Application Example to Smartphone

For example, technologies according to the present disclosure may be applied to a smartphone or the like.

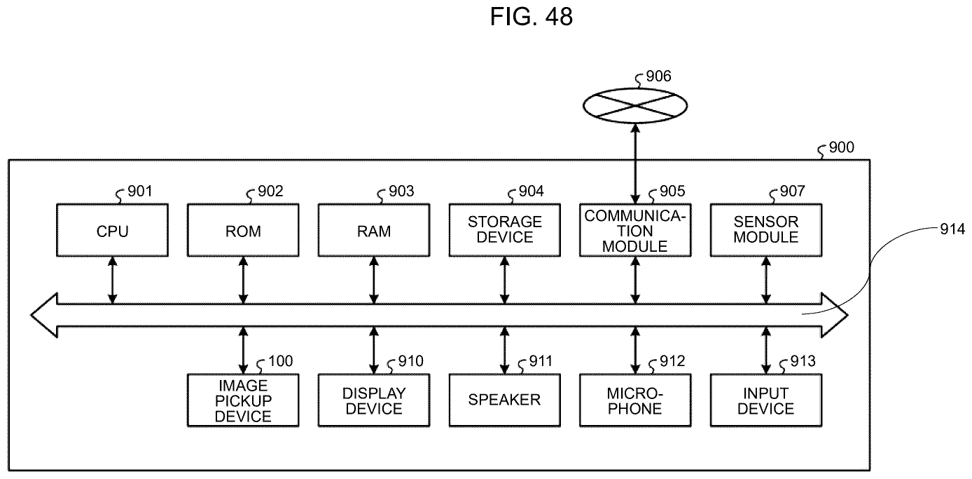

Thus, with reference to FIG. 48, a description will be given of a configuration example of a smartphone 900 as an electronic device to which the present technology is applied. FIG. 48 is a block diagram illustrating an example of a schematic functional configuration of the Smartphone 900 to which a technology according to an embodiment of the present disclosure (present technology) can be applied.

As illustrated in FIG. 48, the smartphone 900 includes a central processing unit (CPU) 901, a read only memory (ROM) 902, and a random access memory (RAM) 903. In addition, the smartphone 900 includes a storage device 904, a communication module 905, and a sensor module 907. Further, the smartphone 900 includes the image pickup device 100, a display device 910, a speaker 911, a microphone 912, an input device 913, and a bus 914. Furthermore, the smartphone 900 may include a processing circuit such as a digital signal processor (DSP) instead of or in addition to the CPU 901.

The CPU 901 functions as an arithmetic processing device and a control device, and controls overall operation in the smartphone 900 or a part thereof according to various programs recorded in the ROM 902, the RAM 903, the storage device 904, or the like. The ROM 902 stores programs, operation parameters, and the like used by the CPU 901. The RAM 903 temporarily stores programs used in execution of the CPU 901, parameters that appropriately change in the execution, and the like. The CPU 901, the ROM 902, and the RAM 903 are connected to each other by the bus 914. In addition, the storage device 904 is a device for data storage included as an example of a storage unit of the smartphone 900. The storage device 904 includes, for example, a magnetic storage device such as a hard disk drive (HDD), a semiconductor storage device, an optical storage device, and the like. The storage device 904 stores programs and various data executed by the CPU 901, various data acquired from the outside, and the like.

The communication module 905 is a communication interface including, for example, a communication device for connecting to a communication network 906. The communication module 905 can be, for example, a communication card for wired or wireless local area network (LAN), Bluetooth (registered trademark), wireless universal serial bus (WUSB), or the like. In addition, the communication module 905 may be a router for optical communication, a router for asymmetric digital subscriber line (ADSL), a modem for various types of communication, or the like. The communication module 905 transmits and receives signals and the like to and from the Internet and other communication devices using a predetermined protocol such as Transmission Control Protocol (TCP)/Internet Protocol (IP). In addition, the communication network 906 connected to the communication module 905 is a network connected in a wired or wireless manner, and is, for example, the Internet, a home LAN, infrared communication, satellite communication, or the like.

The sensor module 907 includes, for example, various sensors such as a motion sensor (for example, an acceleration sensor, a gyro sensor, a geomagnetic sensor, or the like), a biological information sensor (for example, a pulse sensor, a blood pressure sensor, a fingerprint sensor, or the like), or a position sensor (for example, a global navigation satellite system (GNSS) receiver or the like).

The image pickup device 100 is provided on the surface of the smartphone 900, and can pick up an image of an object or the like located on the back side or the front side of the smartphone 900. Specifically, the technology according to an embodiment of the present disclosure (present technology) can be applied to the image pickup device 100. Further, the image pickup device 100 can further include an optical system mechanism (not illustrated) including an image pickup lens, a zoom lens, a focus lens, and the like, and a drive system mechanism (not illustrated) that controls operation of the optical system mechanism.

The display device 910 is provided on the surface of the smartphone 900, and can be, for example, a display device such as a liquid crystal display (LCD) or an organic electro luminescence (EL) display. The display device 910 can display an operation screen, a picked up image acquired by the above-described image pickup device 100, and the like.

The speaker 911 can output, for example, a call voice, a voice accompanying a video content displayed by the display device 910 described above, and the like to the user.

The microphone 912 can collect, for example, a call voice of the user, a voice including a command to activate a function of the smartphone 900, and a voice in a surrounding environment of the smartphone 900.

The input device 913 is a device operated by the user, such as a button, a keyboard, a touch panel, or a mouse. The input device 913 includes an input control circuit that generates an input signal on the basis of information input by the user and outputs the input signal to the CPU 901. By operating the input device 913, the user can input various data or give an instruction on a processing operation to the smartphone 900.

The configuration example of the smartphone 900 has been described above. Each of the above-described components may include a general-purpose member, or may include hardware specialized for a function of each component. Such a configuration can be appropriately changed according to the technical level at the time of implementation.

Since the smartphone 900 has limitations on the size and power consumption of the device, it is strongly required to lower the processing load, and thus, by applying the technology of the present disclosure to the smartphone 900, it is possible to suppress an increase in the amount of data while suppressing deterioration in image quality.

### 10.2 Application Example to Endoscopic Surgery System

For example, the technologies according to the present disclosure may be applied to an endoscopic surgery system.

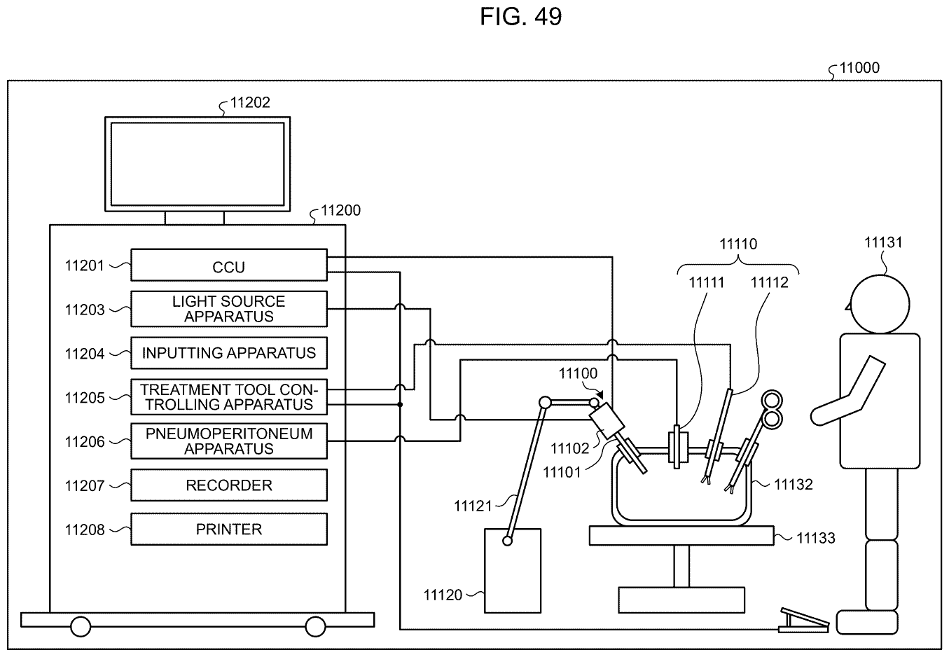

FIG. 49 is a view depicting an example of a schematic configuration of an endoscopic surgery system to which the technology according to an embodiment of the present disclosure (present technology) can be applied.

In FIG. 49, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy treatment tool 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body lumen of the patient 11132, and a camera head 11102 connected to a proximal end of the lens barrel 11101. In the example depicted, the endoscope 11100 is depicted which includes as a hard mirror having the lens barrel 11101 of the hard type. However, the endoscope 11100 may otherwise be included as a soft mirror having the lens barrel 11101 of the soft type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body lumen of the patient 11132 through the objective lens. It is to be noted that the endoscope 11100 may be a direct view mirror or may be a perspective view mirror or a side view mirror.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy treatment tool 11112 for cautery or incision of a tissue, sealing of a blood vessel or the like. A pneumoperitoneum apparatus 11206 feeds gas into a body lumen of the patient 11132 through the pneumoperitoneum tube 11111 to inflate the body lumen in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

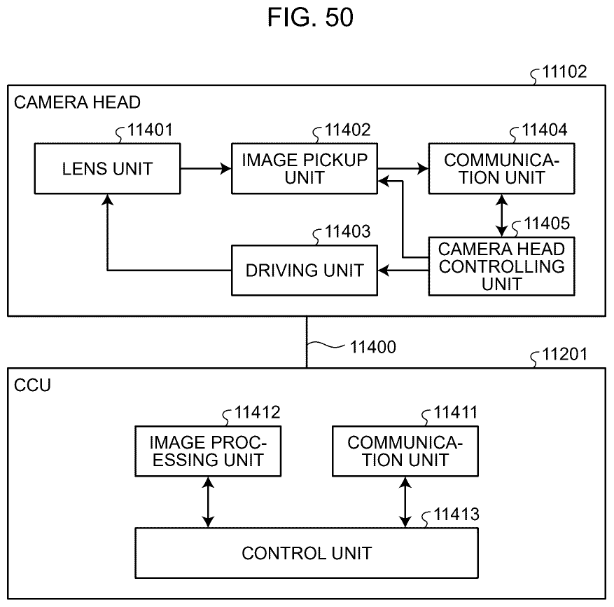

FIG. 50 is a block diagram depicting an example of a functional configuration of the camera head 11102 and the CCU 11201 depicted in FIG. 49.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged.

Thereupon, the control unit 11413 may recognize various objects in the picked up image using various image recognition technologies. For example, the control unit 11413 can recognize a surgical tool such as forceps, a particular living body region, bleeding, mist when the energy treatment tool 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

In the above, an example has been described of the endoscopic surgery system to which the technologies according to the present disclosure can be applied. The technologies according to the present disclosure can be applied to, for example, the endoscope 11100 is the above-described configuration.

Note that, here, the endoscopic surgery system has been described as an example, but in addition, the technologies according to the present disclosure may be applied to, for example, a microscopic surgery system or the like.

### 11. Supplement

In the above, the preferred embodiments of the present disclosure have been described in detail with reference to the accompanying drawings; however, the technical scope of the present disclosure is not limited to such examples. It is obvious that a person having ordinary knowledge in the technical field of the present disclosure can come up with various change examples or modification examples within the scope of the technical idea described in the claims, and it is understood that those examples also belong to the technical scope of the present disclosure of course.

Furthermore, the effects described in the present specification are merely explanatory or exemplary and are not restrictive. That is, the technologies according to the present disclosure may exhibit other effects obvious to those skilled in the art from the description of the present specification, in addition to or in place of the above-described effects.

Note that, the present technology can also have the following configurations.
(1) An image pickup device comprising:
   a semiconductor substrate including a pixel region including a plurality of image pickup elements arranged in an array and an outer peripheral portion surrounding the pixel region;
   a glass substrate provided above the semiconductor substrate;
   a first sealing material that covers the outer peripheral portion of the semiconductor substrate and seals
   a gap between the semiconductor substrate and the glass substrate; and
   a plurality of columnar bodies provided at an inner side from the first sealing material on the semiconductor substrate.
(2) The image pickup device according to (1), wherein the plurality of columnar bodies includes a high refractive index material having a refractive index of from 1.4 to 1.6.
(3) The image pickup device according to (2), wherein the high refractive index material includes an epoxy-based resin, low melting point glass, or an ultraviolet curable resin.
(4) The image pickup device according to any one of (1) to (3), wherein a cross-sectional shape obtained by cutting of each of the columnar bodies on a plane parallel to a plane of the semiconductor substrate is a substantially circular shape or a substantially polygonal shape.
(5) The image pickup device according to (4), wherein each of the columnar bodies having a cross section of the substantially polygonal shape is provided such that a vertex of at least one corner of the substantially polygonal shape is directed toward a center of the pixel region.
(6) The image pickup device according to (4) or (5), wherein the plurality of columnar bodies has the cross section that is smaller as the plurality of columnar bodies is closer to a center of the pixel region.
(7) The image pickup device according to any one of (1) to (6), wherein the plurality of columnar bodies is arranged in a checkered pattern in a plan view.
(8) The image pickup device according to (7), wherein
   the plurality of columnar bodies includes a first columnar body, a second columnar body, a third columnar body, and a fourth columnar body, and
   in a plan view of the semiconductor substrate,
   a first row is constituted by the first columnar body and the second columnar body arranged at a predetermined interval along a first direction,
   a second row is constituted by the third columnar body and the fourth columnar body arranged at the predetermined interval along the first direction,
   the first row and the second row are adjacent to each other along a second direction perpendicularly intersecting the first direction, and
   the first columnar body is located between the third columnar body and the fourth columnar body in the first direction.
(9) The image pickup device according to any one of (1) to (6), wherein the plurality of columnar bodies is randomly arranged in a plan view of the semiconductor substrate.
(10) The image pickup device according to any one of (1) to (3), wherein each of the columnar bodies has a substantially cylindrical shape, a substantially prismatic shape, a substantially conical shape having a vertex upward or downward, a substantially conical shape whose vertex is cut, a substantially pyramidal shape having a vertex upward or downward, a substantially pyramidal shape whose vertex is cut, or a shape in which two substantially conical or substantially pyramidal shapes whose vertexes are cut are stacked.
(11) The image pickup device according to any one of (1) to (10), wherein
   the pixel region includes an effective pixel region and a dummy pixel region surrounding the effective pixel region, and
   the plurality of columnar bodies is provided on at least a part of the dummy pixel region.
(12) The image pickup device according to (11), wherein the dummy pixel region includes the image pickup elements covered with a light shielding film.
(13) The image pickup device according to (11), wherein the plurality of columnar bodies is provided on an extended portion of the first sealing material that expands over at least a part of the dummy pixel region.
(14) The image pickup device according to (13), wherein the extended portion has a slope whose upper surface becomes higher at a position closer to an outer side of the image pickup device, and the plurality of columnar bodies is provided on the slope.
(15) The image pickup device according to (13), wherein the extended portion has a staircase structure whose height becomes higher at a position closer to an outer side of the image pickup device, and the plurality of columnar bodies is provided on the staircase structure.
(16) The image pickup device according to any one of (11) to (15), wherein in the effective pixel region, there is a gap between the semiconductor substrate and the glass substrate.
(17) The image pickup device according to any one of (11) to (15), wherein in the effective pixel region, there is a low refractive index resin having a refractive index lower than that of the columnar bodies between the semiconductor substrate and the glass substrate.
(18) The image pickup device according to (11), further comprising a second sealing material that covers an outer peripheral portion of the image pickup device and is provided at an outer side from the first sealing material.
(19) The image pickup device according to (18), wherein the plurality of columnar bodies includes a light absorbing material that absorbs light having a wavelength within a predetermined wavelength band.
(20) The image pickup device according to (18), wherein the first sealing material includes a light absorbing material that absorbs light having a wavelength within a predetermined wavelength band.
(21) The image pickup device according to (18), wherein the second sealing material includes a light absorbing material that absorbs light having a wavelength within a predetermined wavelength band.
(22) The image pickup device according to (18), wherein a light absorbing layer including a light absorbing material that absorbs light having a wavelength within a predetermined wavelength band is provided in a portion located above the outer peripheral portion of the semiconductor substrate in an upper surface of the glass substrate.
(23) The image pickup device according to (22), wherein the light absorbing layer extends to a portion located above the dummy pixel region in the upper surface of the glass substrate.
(24) The image pickup device according to (18), wherein a light absorbing layer including a light absorbing material that absorbs light having a wavelength within a predetermined wavelength band is provided in a portion located above the outer peripheral portion of the semiconductor substrate in a lower surface of the glass substrate facing the semiconductor substrate.
(25) The image pickup device according to any one of (19) to (24), wherein the light absorbing material includes a material that absorbs light having a wavelength within a visible light band.
(26) The image pickup device according to (25), wherein the material includes carbon black or titanium black.
(27) The image pickup device according to any one of (19) to (24), wherein the light absorbing material includes a material that absorbs light having a wavelength within an infrared light band.
(28) The image pickup device according to (27), wherein the material includes lanthanum hexaboride or cesium-doped tungsten oxide.
(29) The image pickup device according to (18), wherein surface roughening is performed on a portion located above the outer peripheral portion of the semiconductor substrate in an upper surface of the glass substrate.
(30) The image pickup device according to (11), wherein side surfaces of the plurality of columnar bodies are covered with a first covering layer including a first low refractive material having a refractive index lower than that of the plurality of columnar bodies.
(31) The image pickup device according to (11), wherein a side surface of the first sealing material on the effective pixel region's side is covered with a second covering layer including a second low refractive material having a refractive index lower than that of the first sealing material.
(32) The image pickup device according to (30) or (31), wherein the refractive index of the first low refractive material is greater than 1 and less than or equal to 1.4.
(33) The image pickup device according to (32), wherein the first low refractive material includes magnesium fluoride or porous silicon oxide.
(34) The image pickup device according to (18), wherein a side surface of the second sealing material on the effective pixel region's side has a reverse tapered structure, a reverse staircase structure, or an eaves structure.
(35) The image pickup device according to (18), wherein a side surface of the second sealing material on the effective pixel region's side is a roughened surface.
(36) The image pickup device according to (35), wherein the roughened surface is at least a part of the side surface of the second sealing material.
(37) The image pickup device according to (18), wherein an upper surface of the second sealing material is a roughened surface.
(38) The image pickup device according to any one of (34) to (37), wherein there is a gap between the first sealing material and the second sealing material.
(39) An electronic device equipped with an image pickup device,
   the image pickup device including:
   a semiconductor substrate including a pixel region including a plurality of image pickup elements arranged in an array and an outer peripheral portion surrounding the pixel region;
   a glass substrate provided above the semiconductor substrate;
   a first sealing material that covers the outer peripheral portion of the semiconductor substrate and seals a gap between the semiconductor substrate and the glass substrate; and
   a plurality of columnar bodies provided at an inner side from the first sealing material on the semiconductor substrate.

### REFERENCE SIGNS LIST

100 IMAGE PICKUP DEVICE
101 PIXEL ARRAY UNIT
102 VERTICAL DRIVE CIRCUIT
103 COLUMN PROCESSING CIRCUIT
104 HORIZONTAL DRIVE CIRCUIT
105 SYSTEM CONTROL UNIT
108 SIGNAL PROCESSING UNIT
109 DATA STORAGE UNIT
110 PIXEL
111 TRANSFER TRANSISTOR
112 RESET TRANSISTOR
113 AMPLIFICATION TRANSISTOR
114 SELECTION TRANSISTOR
121 LIGHT RECEIVING CHIP
122 CIRCUIT CHIP
131, 136, 400 SEMICONDUCTOR SUBSTRATE
132 ON-CHIP LENS
134, 500 GLASS SUBSTRATE
108
133, 133b, 250 RESIN LAYER
133a, 240, 260 CAVITY
137 EXTENDED ELECTRODE
138 BALL BUMP
139 PASSIVATION
150, 300 EFFECTIVE PIXEL REGION
200, 200a, 200b, 210, 210a SEALING MATERIAL
210t, 210s EXTENDED PORTION
220, 220a, 220A, 220b, 220B, 220c, 220C, 220d, 220D,
220E, 220F, 220G, 220h PILLAR
230, 280 GAP
270 COVERING LAYER
290 BEAD
310 OUTER PERIPHERAL PORTION
310a OUTERMOST PERIPHERAL PORTION
310b OPTICAL BLACK REGION
310c NON-EFFECTIVE PIXEL REGION
350 LIGHT ABSORBING LAYER
352 ROUGH SURFACE
410 COLOR FILTER
420 LIGHT SHIELDING FILM
600 ADHESIVE
700 702 RESIST
900 SMARTPHONE
901 CPU
902 ROM
903 RAM
904 STORAGE DEVICE
905 COMMUNICATION MODULE
906 COMMUNICATION NETWORK
907 SENSOR MODULE
910 DISPLAY DEVICE
911 SPEAKER
912 MICROPHONE
913 INPUT DEVICE
914 BUS
1000 ELECTRONIC DEVICE
1020 IMAGE PICKUP LENS
1030 STORAGE UNIT
1040 PROCESSOR

What is claimed is:

1. An image pickup device comprising:
a semiconductor substrate including a pixel region including a plurality of image pickup elements arranged in an array and an outer peripheral portion surrounding the pixel region;
a glass substrate provided above the semiconductor substrate;
a first sealing material that covers the outer peripheral portion of the semiconductor substrate and seals a gap between the semiconductor substrate and the glass substrate; and
a plurality of columnar bodies provided at an inner side from the first sealing material on the semiconductor substrate.

2. The image pickup device according to claim 1, wherein the plurality of columnar bodies includes a high refractive index material having a refractive index of from 1.4 to 1.6.

3. The image pickup device according to claim 2, wherein the high refractive index material includes an epoxy-based resin, low melting point glass, or an ultraviolet curable resin.

4. The image pickup device according to claim 1, wherein a cross-sectional shape obtained by cutting of each of the columnar bodies on a plane parallel to a plane of the semiconductor substrate is a substantially circular shape or a substantially polygonal shape.

5. The image pickup device according to claim 4, wherein each of the columnar bodies having a cross section of the substantially polygonal shape is provided such that a vertex of at least one corner of the substantially polygonal shape is directed toward a center of the pixel region.

6. The image pickup device according to claim 4, wherein the plurality of columnar bodies has the cross section that is smaller as the plurality of columnar bodies is closer to a center of the pixel region.

7. The image pickup device according to claim 1, wherein the plurality of columnar bodies is arranged in a checkered pattern in a plan view.

8. The image pickup device according to claim 7, wherein
the plurality of columnar bodies includes a first columnar body, a second columnar body, a third columnar body, and a fourth columnar body, and
in a plan view of the semiconductor substrate, a first row is constituted by the first columnar body and the second columnar body arranged at a predetermined interval along a first direction,
a second row is constituted by the third columnar body and the fourth columnar body arranged at the predetermined interval along the first direction,
the first row and the second row are adjacent to each other along a second direction perpendicularly intersecting the first direction, and
the first columnar body is located between the third columnar body and the fourth columnar body in the first direction.

9. The image pickup device according to claim 1, wherein the plurality of columnar bodies is randomly arranged in a plan view of the semiconductor substrate.

10. The image pickup device according to claim 1, wherein each of the columnar bodies has a substantially cylindrical shape, a substantially prismatic shape, a substantially conical shape having a vertex upward or downward, a substantially conical shape whose vertex is cut, a substantially pyramidal shape having a vertex upward or downward, a substantially pyramidal shape whose vertex is cut, or a shape in which two substantially conical or substantially pyramidal shapes whose vertexes are cut are stacked.

11. The image pickup device according to claim 1, wherein
the pixel region includes an effective pixel region and a dummy pixel region surrounding the effective pixel region, and
the plurality of columnar bodies is provided on at least a part of the dummy pixel region.

12. The image pickup device according to claim 11, wherein the dummy pixel region includes the image pickup elements covered with a light shielding film.

13. The image pickup device according to claim 11, wherein the plurality of columnar bodies is provided on an extended portion of the first sealing material that expands over at least a part of the dummy pixel region.

14. The image pickup device according to claim 13, wherein the extended portion has a slope whose upper surface becomes higher at a position closer to an outer side of the image pickup device, and the plurality of columnar bodies is provided on the slope.

15. The image pickup device according to claim 13, wherein the extended portion has a staircase structure whose height becomes higher at a position closer to an outer side of the image pickup device, and the plurality of columnar bodies is provided on the staircase structure.

16. The image pickup device according to claim 11, wherein in the effective pixel region, there is a gap between the semiconductor substrate and the glass substrate.

17. The image pickup device according to claim 11, wherein in the effective pixel region, there is a low refractive index resin having a refractive index lower than that of the columnar bodies between the semiconductor substrate and the glass substrate.

18. The image pickup device according to claim 11, further comprising a second sealing material that covers an outer peripheral portion of the image pickup device and is provided at an outer side from the first sealing material.

19. The image pickup device according to claim 18, wherein the plurality of columnar bodies includes a light absorbing material that absorbs light having a wavelength within a predetermined wavelength band.

20. The image pickup device according to claim 18, wherein the first sealing material includes a light absorbing material that absorbs light having a wavelength within a predetermined wavelength band.

21. The image pickup device according to claim 18, wherein the second sealing material includes a light absorbing material that absorbs light having a wavelength within a predetermined wavelength band.

22. The image pickup device according to claim 18, wherein a light absorbing layer including a light absorbing material that absorbs light having a wavelength within a predetermined wavelength band is provided in a portion located above the outer peripheral portion of the semiconductor substrate in an upper surface of the glass substrate.

23. The image pickup device according to claim 22, wherein the light absorbing layer extends to a portion located above the dummy pixel region in the upper surface of the glass substrate.

24. The image pickup device according to claim 18, wherein a light absorbing layer including a light absorbing material that absorbs light having a wavelength within a predetermined wavelength band is provided in a portion located above the outer peripheral portion of the semiconductor substrate in a lower surface of the glass substrate facing the semiconductor substrate.

25. The image pickup device according to claim 19, wherein the light absorbing material includes a material that absorbs light having a wavelength within a visible light band.

26. The image pickup device according to claim 25, wherein the material includes carbon black or titanium black.

27. The image pickup device according to claim 19, wherein the light absorbing material includes a material that absorbs light having a wavelength within an infrared light band.

28. The image pickup device according to claim 27, wherein the material includes lanthanum hexaboride or cesium-doped tungsten oxide.

29. The image pickup device according to claim 18, wherein surface roughening is performed on a portion located above the outer peripheral portion of the semiconductor substrate in an upper surface of the glass substrate.

30. The image pickup device according to claim 11, wherein side surfaces of the plurality of columnar bodies are covered with a first covering layer including a first low refractive material having a refractive index lower than that of the plurality of columnar bodies.

31. The image pickup device according to claim 11, wherein a side surface of the first sealing material on the effective pixel region's side is covered with a second covering layer including a second low refractive material having a refractive index lower than that of the first sealing material.

32. The image pickup device according to claim 30, wherein the refractive index of the first low refractive material is greater than 1 and less than or equal to 1.4.

33. The image pickup device according to claim 32, wherein the first low refractive material includes magnesium fluoride or porous silicon oxide.

34. The image pickup device according to claim 18, wherein a side surface of the second sealing material on the effective pixel region's side has a reverse tapered structure, a reverse staircase structure, or an eaves structure.

35. The image pickup device according to claim 18, wherein a side surface of the second sealing material on the effective pixel region's side is a roughened surface.

36. The image pickup device according to claim 35, wherein the roughened surface is at least a part of the side surface of the second sealing material.

37. The image pickup device according to claim 18, wherein an upper surface of the second sealing material is a roughened surface.

38. The image pickup device according to claim 34, wherein there is a gap between the first sealing material and the second sealing material.

39. An electronic device equipped with an image pickup device,
the image pickup device including:
a semiconductor substrate including a pixel region including a plurality of image pickup elements arranged in an array and an outer peripheral portion surrounding the pixel region;
a glass substrate provided above the semiconductor substrate;
a first sealing material that covers the outer peripheral portion of the semiconductor substrate and seals a gap between the semiconductor substrate and the glass substrate; and
a plurality of columnar bodies provided at an inner side from the first sealing material on the semiconductor substrate.
